(19) United States
(12) Patent Application Publication
(10) Pub. No.: US 2005/0207751 A1
(43) Pub. Date: Sep. 22, 2005

(54) Replenishing method of development replenisher in automatic developing equipment of photosensitive lithographic printing plate

(75) Inventor: Shuichi Takamiya, Haibara-gun (JP)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: FUJI PHOTO FILM CO., LTD., Minami-Ashigara-shi (JP)

(21) Appl. No.: 11/080,570

(22) Filed: Mar. 16, 2005

(30) Foreign Application Priority Data
Mar. 17, 2004 (JP) 2004-076034
Jan. 28, 2005 (JP) 2005-021302

(51) Int. Cl. G03F 7/00

(52) U.S. Cl. 396/571

(57) ABSTRACT

A replenishing method of a development replenisher in an automatic developing equipment of photosensitive lithographic printing plate including developing plural photosensitive lithographic printing plates having been subjected to exposure processing with a developer containing an electrolyte and a development inhibitor, which includes measuring an electric conductivity of the developer; comparing the measured electric conductivity value with a predetermined electric conductivity standard value; and when the electric conductivity value of the developer is lower than the electric conductivity standard value, replenishing a development replenisher having a concentration of the development inhibitor higher than that of the developer.

This application is based on Japanese Patent application JP 2004-076034, filed Mar. 17, 2004, the entire content of which is hereby incorporated by reference. This claim for priority benefit is being filed concurrently with the filing of this application.

### BACKGROUND OF THE INVENTION

1. Field of the Invention

The present invention relates to an automatic development method of, for example, a photosensitive lithographic printing plate and an automatic developing equipment thereof. In particular, the invention relates to a technology for minimizing the fluctuation in sensitivity of a developer against changes of the development processing conditions using a developer containing a development inhibitor.

2. Description of the Related Art

In recent years, the development of lasers is conspicuous. In particular, as solid lasers and semi-conductor lasers having a light-emitting region in the range of near infrared light to infrared light, ones having a high output and a small size have become easily available. As an exposure source of the system for achieving direct plate making from this digital data, these lasers are very useful. As an image recording material suitable for writing with laser, for example, JP-A-7-285275 proposes a positive image recording material containing a binder such as cresol resins, a substance which absorbs light to generate heat, and a compound which is heat decomposable and can substantially lower the solubility of the binder in the state before occurrence of the decomposition such as quinonediazide. This is of a heat mode type in which the foregoing substance which absorbs light to generate heat causes heat generation in an exposed area upon irradiation with near infrared light, thereby making the exposed area soluble in an alkali. However, in this image recording material, since the heat is absorbed on aluminum as a support, the heat efficiency is low so that the solubility in an alkaline development processing liquid in the development step was not satisfactory. For this reason, the alkali concentration of the developer was increased, thereby ensuring the solubility in the exposed area. Now, a lithographic printing plate precursor of the heat mode type involved such a problem that the resistance of an image area against dissolution in the alkaline development processing liquid is low under such a high-concentration alkaline condition so that whenever even a small scratch is present on the surface of the image recording material, the image area is dissolved, thereby generating a defect in the image area. In particular, in a positive lithographic printing plate precursor using a high molecular compound having high solubility in an alkaline aqueous solution, the foregoing tendency was more remarkable. Accordingly, in increasing the alkali concentration of the alkaline developer without generating a residual film in a non-image area, there is a limit. Thus, it was difficult to form a highly sharp and clear image without giving a defect to the formed image area. In particular, in an image containing halftone dot areas and thin lines, it is required to realize high sharpness and an enhancement of reproducibility. For the purpose of achieving this, in an automatic developing equipment of photosensitive lithographic printing plate, a replenishing system due to aging and due to processing in which a development replenisher is replenished with time in a developing tank where a developer is stored, a plate area of a lithographic printing plate to be processed is measured, and the development replenisher is replenished in an amount corresponding to the measured value (this system will be hereinafter referred to as “area-based replenishing system due to aging”) or a replenishing system in which the deterioration of a developer is measured in terms of an electric conductivity, and a replenisher is replenished following previously programmed instructions is employed as a measure for managing the sensitivity of the developer.

However, in such an area-based replenishing system due to aging, a high-precision plate area measurement device of lithographic printing plate is required in a development processing section of the automatic developing equipment, and therefore, there was a problem of complication of the structure and an increase of the costs. Also, it is difficult to distinguish whether the photosensitive side of the lithographic printing plate is a single side or double sides (hereinafter referred to as “single side/double sides”) and to distinguish the plate type (such as a plate having a different coating amount of the photosensitive layer). For these reasons, there was encountered such a problem that if a necessary replenishing amount of the development replenisher changes due to the changes of the plate area, single side/double sides and plate type of the lithographic printing plate, it becomes difficult to adequately achieve the replenishment of the development replenishing amount. Also, in the replenishing system in which the deterioration of a developer is measured in terms of an electric conductivity, and a replenisher is replenished following previously programmed instructions, it was difficult for the development system containing a development inhibitor to perform proper replenishment as a factor contributing to the development in addition to the electric conductivity.

### SUMMARY OF THE INVENTION

An object of the invention is to provide a development replenishing method of an automatic developing equipment of photosensitive lithographic printing plate capable of minimizing the fluctuation in sensitivity of a developer containing an electrolyte and a development inhibitor against changes of the development processing conditions while employing a cheap construction as a developing section of the automatic developing equipment, in the case of development processing of a photosensitive lithographic printing plate having been subjected to exposure processing,.

Incidentally, in the invention, the “development replenisher” as referred to herein means a processing liquid to be replenished for the purpose of keeping the development performance constant. In general, as this replenisher, one prepared by diluting a stock solution of replenisher with a diluent (for example, water) or a stock solution of replenisher itself without dilution is useful. However, in the invention, the “development replenisher” means one prepared by diluting a stock solution of replenisher with a diluent. Also, examples of the replenishing method include a method in which a replenisher prepared by previous dilution is replenished in the developer and a method in which a stock solution of replenisher and a diluent are individually replenished directly in the developer.

Further, in the invention, as an electric conductivity sensor for measuring the electric conductivity value of the developer, known means such as an alternating current electric conductivity meter, an alternating current bridge meter, and other electric conductivity meters can be used. Also, with respect to the measuring current value or oscillation frequency, etc. of the measuring instruments, the optimum condition is different depending upon the developer composition, etc. However, from the viewpoint of devices or for the purpose of preventing the electrolysis of a water-soluble developer, it is preferable that the current value is low to some extent, and the current value is preferably from several hundreds mA to several μA. Also, the frequency is preferably from several hundreds Hz to several hundreds kHz in view of the relationship with a capacitance component in the developer.

The electric conductivity of the developer containing an electrolyte depends upon the temperature of an aqueous solution, and when the liquid temperature increases, the electric conductivity value decreases. Accordingly, it is more preferable that the electric conductivity value is measured by a measuring instrument equipped with a temperature sensor and a temperature compensatory circuit. Also, in a controlling device for controlling the replenishment, it is possible to compensate the temperature by reducing the electric conductivity value into an electric conductivity value at a preset temperature from the actually measured resistance value of liquid and liquid temperature. With respect to the position at which the sensor of the alternating current electric conductivity meter, the alternating current bridge meter or other electric conductivity meters is placed, any place is employable so far as the sensor is immersed in the developer at the time of measurement, whereby the alternating current electric conductivity value of the developer can be measured. For example, the position in a developer circulation system of the automatic developing equipment, especially the position in a developing tank or a circulating pipe, is preferable. Also, as a detection section, known cells in which platinum, stainless steel, etc. is used as an electrode can be used.

The foregoing object of the invention is achieved by the following replenishing method of a development replenisher in an automatic developing equipment of photosensitive lithographic printing plate.
(1) A replenishing method of a development replenisher in an automatic developing equipment of photosensitive lithographic printing plate including: developing plural photosensitive lithographic printing plates having been subjected to exposure processing with a developer containing an electrolyte and a development inhibitor; and keeping a developer activity of the developer constant, which comprises: measuring an electric conductivity of the developer; comparing the measured electric conductivity value with a predetermined electric conductivity standard value; and when the electric conductivity value of the developer is lower than the electric conductivity standard value, replenishing a development replenisher having a concentration of the development inhibitor higher than that of the developer.
(2) The replenishing method of a development replenisher in an automatic developing equipment of photosensitive lithographic printing plate as set forth above in (1), wherein an electric conductivity value operated from a total processing amount of the photosensitive lithographic printing plate having been processed with the developer is used as the electric conductivity standard value.
(3) The replenishing method of a development replenisher in an automatic developing equipment of photosensitive lithographic printing plate as set forth above in (1), wherein an electric conductivity value operated from replenisher displacement rate which is a rate of the development replenisher replenished in the developer in the developer is used as the electric conductivity standard value.
(4) The replenishing method of a development replenisher in an automatic developing equipment of photosensitive lithographic printing plate as set forth above in (1), wherein an electric conductivity value operated from: a replenishing rate due to aging which is a rate of an amount of replenisher due to aging operated from an operation time and a stopping time of the automatic developing equipment of photosensitive lithographic printing plate to a total replenishing amount; and replenisher displacement rate which is a rate of the development replenisher replenished in the developer in the developer, is used as the electric conductivity standard value.
(5) The replenishing method of a development replenisher in an automatic developing equipment of photosensitive lithographic printing plate as set forth above in (1), wherein the concentration of the development inhibitor in the development replenisher is in the range of from 1.1 to 50 times that in the developer.

According to the invention, in developing plural exposed photosensitive lithographic printing plates with a developer comprising an aqueous solution containing an electrolyte and a development inhibitor, by measuring an electric conductivity value of the developer and when the measured electric conductivity value of the developer is lower than a predetermined electric conductivity standard value, replenishing the developer with a development replenisher, it is possible to prevent the fluctuation in activity of the developer caused due to changes of the processing conditions (size and kind of the photosensitive lithographic printing plate) from occurring while employing a simple and cheap device construction and to realize the automatic development processing with high sensitivity stability.

### BRIEF DESCRIPTION OF THE DRAWINGS

FIG. 1 is a constructive view of the first embodiment of an automatic developing equipment for carrying out the development replenishing method according to the invention.

FIG. 2 is a flow chart explaining the basic control processing for replenishing a development replenisher.

FIG. 3 is a flow chart explaining the first control processing which specifically exhibits the basic control processing of FIG. 2.

FIG. 4 is a flow chart explaining the second control processing.

FIG. 5 is a flow chart explaining the third control processing.

FIG. 6 is a constructive view of an automatic developing equipment according the second embodiment of the invention.

### DETAILED DESCRIPTION OF THE INVENTION

First of all, an alkaline development processing liquid which is used in a plate making method of a lithographic printing plate of the invention will be described below.

The alkaline development processing liquid which is used for the development processing (hereinafter often referred to simply as “developer”) is an alkaline aqueous solution and can be properly chosen among conventionally known alkaline aqueous solutions.

Examples of the alkaline aqueous solution include developers comprising an alkali silicate or a non-reducing sugar and a base. Of these, ones having a pH of from 12.5 to 14.0 are especially preferable.

The foregoing alkali silicate is one which when dissolved in water, becomes alkaline, and examples thereof include alkali metal silicates such as sodium silicate, potassium silicate, and lithium silicate and ammonium silicate.

The alkali silicate can be used singly or in combinations of two or more kinds thereof.

In the foregoing alkaline aqueous solution, the developability can be easily adjusted by a mixing ratio of silicon oxide SiO₂ as a component of the silicate to an alkali oxide M₂O (wherein M represents an alkali metal or an ammonium group) and adjustment of the concentration.

Of the foregoing alkaline aqueous solutions, ones having a mixing ratio of the silicon oxide SiO₂ to the alkali oxide M₂O (SiO₂/M₂O molar ratio) of from 0.5 to 3.0 are preferable. The SiO₂/M₂O (molar ratio) is more preferably from 1.0 to 2.0.

When the SiO₂/M₂O ratio is less than 0.5, the alkali strength is strong so that the alkaline aqueous solution causes harmful effects such as etching of general-purpose aluminum plates as a support of a lithographic printing plate precursor. On the other hand, when it exceeds 3.0, the developability may possibly be lowered.

Also, the concentration of the alkali silicate in the developer is preferably from 1 to 10% by weight, more preferably from 3 to 8% by weight, and most preferably from 4 to 7% by weight based on the weight of the alkaline aqueous solution. When the concentration of the alkali silicate in the developer is less than 1% by weight, the developability and processing ability may possibly be lowered. On the other hand, when it exceeds 10% by weight, precipitation or formation of crystal likely occurs. Further, gelation likely occurs in the neutralization at the time of discharging the waste liquid, thereby possibly hindering the treatment of the waste liquid.

In the developer comprising a non-reducing sugar and a base, the “non-reducing sugar” as referred to herein means a sugar not having reducing properties because it does not have a free aldehyde group or ketone group and is classified into a trehalose type oligosaccharide in which reducing groups are bonded to each other, a glycoside in which a reducing group of a sugar is bonded to a non-sugar, and a sugar alcohol which has been reduced upon hydrogenation to a sugar. In the invention, all of these sugars can be preferably used.

Examples of the trehalose type oligosaccharide include saccharose and trehalose; and examples of the glycoside include alky glycosides, phenol glycosides, and mustard oil glycosides.

Examples of the sugar alcohol include D,L-arabitol, ribitol, xylitol, D,L-sorbitol, D,L-mannitol, D,L-iditol, D,L-talitol, dulcitol, and allodulcitol. Further, maltitols obtained by hydrogenation of disaccharides and reductants (for example, reducing starch syrup) obtained by hydrogenation of oligosaccharides can be preferably enumerated.

Of these, sugar alcohols and saccharose are preferable as the non-reducing sugar; and D-sorbitol, saccharose, and reducing starch syrup are especially preferable in view of the matter that they have a buffering action in a proper pH region.

These non-reducing sugars may be used singly or in combinations of two or more kinds thereof The proportion of the non-reducing sugar in the developer is preferable from 0.1 to 30% by weight, and more preferably from 1 to 20% by weight.

In the foregoing alkali silicate or non-reducing sugar, an alkaline agent as the base can be properly chosen among conventionally known compounds and combined.

Examples of the alkaline agent include inorganic alkaline agents (for example, sodium hydroxide, potassium hydroxide, lithium hydroxide, trisodium phosphate, tripotassium phosphate, triammonium phosphate, disodium phosphate, dipotassium phosphate, diammonium phosphate, sodium carbonate, potassium carbonate, ammonium carbonate, sodium hydrogencarbonate, potassium hydrogencarbonate, ammonium hydrogencarbonate, sodium borate, potassium borate, and ammonium borate), potassium citrate, tripotassium citrate, and sodium citrate.

Further, organic alkaline agents such as monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropylamine, diisopropanolamine, ethyleneimine, ethylenediamine, and pyridine can be preferably enumerated.

These alkaline agents can be used singly or in combinations of two or more kinds thereof.

Of these, sodium hydroxide and potassium hydroxide are preferable. This is because by adjusting the addition amount against the non-reducing sugar, it becomes possible to adjust the pH in a broad pH region. Also, trisodium phosphate, tripotassium phosphate, sodium carbonate, potassium carbonate, and the like are preferable because they have a buffering action by themselves.

The alkaline development processing liquid of the invention can further contain a development inhibitor from the viewpoint of revealing a dissolution suppressing force against the image area. Examples of the development inhibitor include the following alkylene oxide adducts.

[Straight-chain Type Alkylene Oxide Adduct]

Examples of a straight-chain type alkylene oxide adduct which is used in the invention include compounds represented by the following general formula (I).
R—O-(A)ₘ-(B)ₙ—H (I)

In the formula (I), R represents a hydrogen atom, an alkyl group or an alkenyl group each having from 1 to 30 carbon atoms, or an aryl group having from 6 to 48 carbon atoms; A and B are different from each other and each represents either —CH₂CH₂O— or —CH₂CH(CH₃)O—; and m and n each presents 0 or an integer of from 1 to 50, provided that m and n do not represent 0 at the same time.

In the foregoing formula (I), the alkyl group or alkenyl group represented by R may be branched; and the alkyl group, the alkenyl group, and the aryl group may each have a substituent. Examples of the substituent include an alkyl group having from 1 to 20 carbon atoms, a halogen atom, an aryl group having from 6 to 15 carbon atoms, an aralkyl group having from 7 to 17 carbon atoms, an alkoxy group having from 1 to 20 carbon atoms, an alkoxycarbonyl group having from 2 to 20 carbon atoms, and an acyl group having from 2 to 15 carbon atoms.

In the foregoing compounds, when both A and B are present, the compound may be a random or block copolymer. Also, in the compounds, the total sum of m and n is generally from 2 to 50, preferably from 2 to 30, and more preferably from 2 to 20.

In the foregoing compounds, when a propyleneoxy group is present, it is desired that the compound is present within the range where the solubility in water of the compound is tolerable.

Further, specific examples of the straight-chain type alkylene oxide adduct represented by the formula (I) include compounds represented by the following formulae (1) to (6).
HO-(A)ₘ-(B)ₙ—H (1)
CₚH₂ₚ₊₁—O-(A)ₘ-(B)ₙ—H (2)

(p: an integer of from 1 to 30)
C_{q}H_{2q-1}—O-(A)ₘ-(B)ₙ—H (3)

(q: an integer of from 2 to 30)

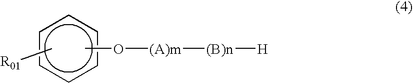

In the formula, R₀₁ represents a hydrogen atom or an optionally branched alkyl group having from 1 to 20 carbon atoms.

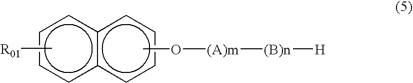

In the formula, R₀₁ represents a hydrogen atom or an optionally branched alkyl group having from 1 to 20 carbon atoms.

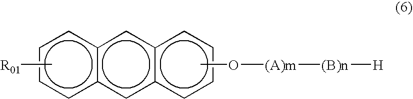

In the formula, R₀₁ represents a hydrogen atom or an optionally branched alkyl group having from 1 to 20 carbon atoms.

In the foregoing formulae (1) to (6), the definitions of A, B, n and m are synonymous with those in the formula (I).

Of the compounds represented by the foregoing formulae (1) to (6), compounds represented by the formula (4) are preferably used. Above all, compounds in which R₀₁ represents an alkyl group having from 1 to 10 carbon atoms, preferably from 1 to 4 carbon atoms, and more preferably from 1 to 3 carbon atom are preferable.

In general, the molecular weight of the straight-chain type alkylene oxide adduct is suitably from 50 to 10,000 from the standpoints of revealing a sufficient dissolution suppressing force against the image area and revealing sufficient developability against the non-image area. The molecular weight is preferably from 100 to 5,000, and most preferably 500 to 3,500.

[Branched Type Alkylene Oxide Adduct]

The “branched type alkylene oxide adduct” as referred to herein means a compound having two or more groups represented by the following formula (II) in the molecular structure thereof.
-(A)ₘ-(B)ₙ—H (II)

In the formula, A and B are different from each other and each represents either —CH₂CH₂O— or —CH₂CH(CH₃)O—; and m and n each presents 0 or an integer of from 1 to 50, provided that m and n do not represent 0 at the same time. However, the branched type alkylene oxide adduct as referred to herein does not include polyalkylene glycols such as polyethylene glycol, polypropylene glycol, and ethylene oxide-propylene oxide condensates.

In the foregoing compounds, where both A and B are present, the compound may be a random or block copolymer. Also, in the formula (II), the total sum of m and n is generally from 2 to 50, preferably from 2 to 30, and especially preferably from 2 to 20.

Specific examples of the branched type alkylene oxide adduct which is used in the invention include (1) compounds having two or more groups represented by —O-(A)ₘ-(B)ₙ—H (wherein A, B, m and n are synonymous with those in the formula (II)) in the molecular structure thereof, and (2) compounds having two or more groups represented by -(A)ₘ-(B)ₙ—H (wherein A, B, m and n are synonymous with those in the formula (II)) in the molecular structure thereof In the foregoing compounds (2), the two or more groups represented by -(A)ₘ-(B)ₙ—H may be bonded to the same nitrogen atom or to a different nitrogen atom from each other.

The branched type alkylene oxide adduct which is used in the invention has two or more, specifically from 2 to 20, preferably not more than 10, and more preferably not more than 8 of the foregoing group (II).

The total addition molar number of the alkylene oxide in the branched alkylene oxide adduct is from 2 to 200 moles per molecule, preferably from 2 to 100 moles per molecule, and more preferably from 2 to 50 moles per molecule.

In the foregoing compounds, when a propyleneoxy group is present, it is desired that the compound is present within the range where the solubility in water of the compound is tolerable.

Further, specific examples of the branched type alkylene oxide adduct which is used in the invention include compounds represented by the following formulae (III), (IV) and (IV′).

Compounds Represented by the Formula (III)

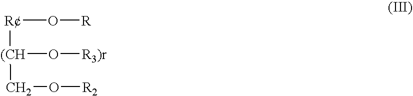

In the formula (III), r represents an integer of from 1 to 10; and R₁, R₂ and R₃ each independently represents a hydrogen atom or a group represented by the following formula (II).
-(A)ₘ-(B)ₙ—H (II)

In the formula (II), A and B are different from each other and each represents either —CH₂CH₂O— or —CH₂CH(CH₃)O—; and m and n each presents 0 or an integer of from 1 to 50, provided that m and n do not represent 0 at the same time. However, at least two of R₁, R₂ and R₃ represent a group represented by the foregoing formula (II).

In the formula (III), r preferably represents an integer of from 1 to 6, and especially preferably an integer of from 1 to 4.

Examples of the branched type alkylene oxide adduct represented by the formula (III) include alkylene oxide addition compounds of sugar alcohols (for example, D,L-threitol, D,L-arabitol, ribitol, xylitol, D,L-sorbitol, D,L-mannitol, D,L-iditol, D,L-talitol, dulcitol, and allodulcitol) and alkylene oxide addition compounds of glycerin. In general, these compounds are commercially available, and examples of commercial products include a trade name SORBITOL EO(30) (manufactured by Nikko Chemical Co., Ltd.).

Other specific examples of the branched alkylene oxide adduct include alkylene oxide adducts of polyglycerins obtained by condensation of a sugar alcohol (for example, diglycerin, triglycerin, tetraglycerin, pentaglycerin, and hexaglycerin).

Compounds Represented by the Formulae (IV) and (IV′)

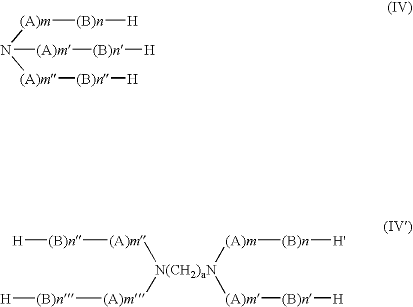

In the formulae (IV) and (IV′), A and B are different from each other and each represents either —CH₂CH₂O— or —CH₂CH(CH₃)O—; m and n each presents 0 or an integer of from 1 to 50, provided that m and n do not represent 0 at the same time; m′ and n′ each presents 0 or an integer of from 1 to 50, provided that m′ and n′ do not represent 0 at the same time; m″ and n″ each presents 0 or an integer of from 1 to 50, provided that m″ and n″ do not represent 0 at the same time; and m″′ and n″′ each presents 0 or an integer of from 1 to 50, provided that m″′ and n″′ do not represent 0 at the same time. In the formula (IV′), a represents an integer of from 2 to 12.

Examples of the compound represented by the formula (IV) include a triethanolamine EO adduct.

Examples of the branched type alkylene oxide adduct represented by the formula (IV′) include an ethylenediamine EO adduct, an ethylenediamine EO/PO adduct, an ethylenediamine PO adduct, and compounds described in the product catalogue for a trade name “TETRONIC”, manufactured by Asahi Denka Co., Ltd.

Other examples of the branched type alkylene oxide adduct include a trimethylolpropyl ether EO adduct, a trimethylolpropyl ether EO/PO adduct, and a trimethylolpropyl ether PO adduct.

In general, the molecular weight of the branched type alkylene oxide adduct which is used in the invention is suitably from 50 to 10,000 from the standpoints of revealing a sufficient dissolution suppressing force against the image area and revealing sufficient developability against the non-image area. The molecular weight is preferably from 100 to 5,000, and most preferably 500 to 3,500.

In the alkaline development processing liquid, the foregoing development inhibitor can be used singly or in combinations of two or more thereof When the development inhibitor is contained in the alkaline development processing liquid, its content is generally from 0.001 to 10.0% by weight, preferably from 0.01 to 5.0% by weight, and especially preferably from 0.05 to 1.0% by weight.

As described previously, a developer containing an alkali silicate or a non-reducing sugar and a base is used the alkaline development processing liquid. Li⁺, Na⁺, K⁺, and NH₄⁺ have hitherto been used as its cation component. Above all, in a system containing many cations having a small ion radius, though it has high permeability into the image recording layer and excellent developability, it dissolves even an image area therein, thereby generating an image defect. Accordingly, in order to increase the alkali concentration, there is some limit. For the sake of achieving complete processing such that the image recording layer (residual film) does not remain in a non-image area without generating a defect in the image area, it was required to delicately set up the liquid property condition.

However, by using cations having a large ion radius as the foregoing cation component, it is possible to suppress the permeability of the developer into the image recording layer and to enhance an effect for suppressing the dissolution of an image area without lowering the alkali concentration, i.e., developability.

In addition to the foregoing alkali metal cations and ammonium ion, other cations can be used as the cation component.

The concentration of the development inhibitor in the developer is preferably from 0.001 to 10% by weight, more preferably from 0.005 to 1% by weight, and most preferably from 0.01 to 0.5% by weight. The replenisher of the alkaline developer to be used in the plate making method of the invention means a liquid to be used. In the case where the development replenisher is prepared, the active ingredients and optional ingredients are not particularly limited and may be the same formulation as in the alkaline development processing liquid or one in which the alkali concentration or mixing ratio (SiO₂/M₂O) is adjusted according to the customary manner. However, it is required that the concentration of the development inhibitor is higher than the concentration of the development processing liquid, and it is preferably from 1.1 to 50 times, more preferably from 2 to 25 times, and further preferably from 3 to 15 times. When the concentration of the development inhibitor is equal to or less than the concentration of the alkaline development processing liquid as the base, an effect for suppressing the dissolution in the unexposed area is deteriorated. When the concentration of the development inhibitor is 1.1 times or more the concentration of the processing liquid, an effect for enhancing the concentration of the development inhibitor becomes remarkable. Also, even when it exceeds 50 times, any more enhancement of the effect is no longer observed, but rather, the developability of the exposed area may possibly be deteriorated, and therefore, such is not preferable.

In the method of the invention, by using the replenisher having a high concentration of the development inhibitor, the development inhibitor for keeping a valance of the developability compensates a lowering of the function caused due to the influence of an insoluble matter or an eluate of the active ingredients, whereby the constant function is always revealed. Thus, it is possible to stably carry out the plate making with a good development performance and a good balance between the image area and the non-image area over a long period of time. Also, as the foregoing replenisher, not only the development inhibitor but also the foregoing aqueous solution having a high alkali strength in which the content of a component having a higher alkali concentration than the developer for development is increased can be used. In this case, however, taking into consideration the resistance to solubility in alkaline aqueous solution of the lithographic printing plate precursor, the development inhibitor should be selected within the range where it does not affect fine image areas such as thin lines and halftone dots. The replenishment may be carried out at any of every fixed time period after passing the plate. Also, the replenishment amount is a numeral obtained by dividing the total replenishment amount by the processing amount and is in the range of from 20 mL/m² to 500 mL/m².

For the purpose of further enhancing the development performance, the following additives can be added in the alkaline development processing liquid of the invention.

Examples of the additives include neutral salts (for example, NaCl, KCl, and KBr) as described in JP-A-58-75152; chelating agents (for example, EDTA and NTA) as described in JP-A-58-190952; complexes (for example, [Co(NH₃)₆]Cl₃ and CoCl₂.6H₂O) as described JP-A-59-121336; anionic or ampholytic surfactants (for example, sodium alkylnaphthalene-sulfonates and n-tetradecyl-N,N-dihydroxyethylbetaine) as described in JP-A-50-51324; nonionic surfactants (for example, tetramethyldecynediol) as described in U.S. Pat. No. 4,374,920; cationic polymers (for example, a methyl chloride quaternary compound of p-dimethylaminomethyl polystyrene) as described in JP-A-55-95946; ampholytic high molecular electrolytes (for example, a copolymer of vinylbenzyl trimethylammonium chloride and sodium acrylate) as described in JP-A-56-142528; reducing inorganic salts (for example, sodium sulfite) as described in JP-A-57-192951; inorganic lithium compounds (for example, lithium chloride) as described in JP-A-58-59444; organometallic surfactants containing, for example, organic Si or Ti, as described in JP-A-59-75255; organoboron compounds as described in JP-A-59-84241; and quaternary ammonium salts (for example, tetraalkylammonium oxides) as described in EP 101010.

The lithographic printing plate having been subjected to development processing using the alkaline development processing liquid and the replenisher is subjected to post-processing with a rinse liquid containing washing water, a surfactant, etc. and a desensitizing liquid containing gum arabic and a starch derivative. For this post-processing, various combinations of these processing liquids can be employed.

A heat-sensitive positive lithographic printing plate which is used in the plate making method of the invention will be described below.

[Heat-sensitive Positive Lithographic Printing Plate]

The heat-sensitive positive lithographic printing plate which is used in the plate making method of the invention is provided with an image recording layer containing an infrared absorbing dye as an essential component and usually further containing an alkali-soluble resin, etc. on a support

The heat-sensitive positive lithographic printing plate (hereinafter often referred to as “lithographic printing plate precursor”) will be described below in detail. First of all, the construction of the image recording layer will be described below.

[Infrared Absorbing Dye]

In the invention, the infrared absorbing dye to be used in the image recording layer is not particularly limited so far as it is a dye which absorbs infrared light to generate heat, and a variety of dyes which are known as an infrared absorbing dye can be used.

As the infrared absorbing dye, commercially available dyes and known infrared absorbing dyes described in publications (for example, Dye Handbook, compiled by The Society of Synthetic Organic Chemistry, Japan and published in 1970) can be utilized. Specific examples thereof include dyes such as azo dyes, metal complex salt azo dyes, pyrazolone azo dyes, quinoneimine dyes, methine dyes, and cyanine dyes. In the invention, of these dyes, dyes which absorb infrared light or near infrared light are especially preferable from the standpoint of the matter that they are preferable for utilization with laser which emits infrared light or near infrared light.

Examples of the dye which absorbs infrared light or near infrared light include cyanine dyes described in JP-A-58-125246, JP-A-59-84356, JP-A-59-202829, JP-A-60-78787, and the like; methine dyes described in JP-A-58-173696, JP-A-58-181690, JP-A-58-194595, and the like; naphthoquinone dyes described in JP-A-58-112793, JP-A-58-224793, JP-A-59-48187, JP-A-59-73996, JP-A-60-59240, JP-A-60-63744, and the like; squalirium coloring matters described in JP-A-58-112792 and the like; and cyanine dyes described in British Patent No. 434,875 and the like.

Also, near infrared absorbing sensitizers described in U.S. Pat. No. 5,156,938 are preferably used as the dye. Also, substituted aryl benzo(thio)pyrylium salts described in U.S. Pat. No. 3,881,924, trimethine thiapyrylium salts described in JP-A-57-142645 (counterpart to U.S. Pat. No. 4,327,169), pyrylium based compounds described in JP-A-58-181051, JP-A-58-220143, JP-A-59-41363, JP-A-59-84248, JP-A-59-84249, JP-A-59-146063, and JP-A-59-146061, cyanine dyes described in JP-A-59-216146, pentamethine thiopyrylium salts described in U.S. Pat. No. 4,283,475, pyrylium compounds described in JP-B-5-13514 and JP-B-5-19702, and the like; and commercially available dyes including Epolight III-178, Epolight III-130, and Epolight III-125, all of which are manufactured by Epolin, Inc. are especially preferable.

Infrared absorbing dyes expressed by the formulae (I) and (II) in U.S. Pat. No. 4,756,993 are especially preferable as the infrared absorbing dye to be used in the image recording layer. These coloring matters exhibit a very strong mutual action with an alkali-soluble resin and are excellent in the alkali-resistant developability in an unexposed area of the image recording layer.

The addition amount of the infrared absorbing dye of the image recording layer is suitably from 0.01 to 50% by weight, preferably from 0.1 to 50% by weight, and especially preferably from 0.1 to 30% by weight based on the weight of the image recording layer from the viewpoints of sensitivity and uniformity of the image recording layer.

Specific examples of the infrared absorbing dye will be given below, but it should not be construed that the invention is limited thereto. 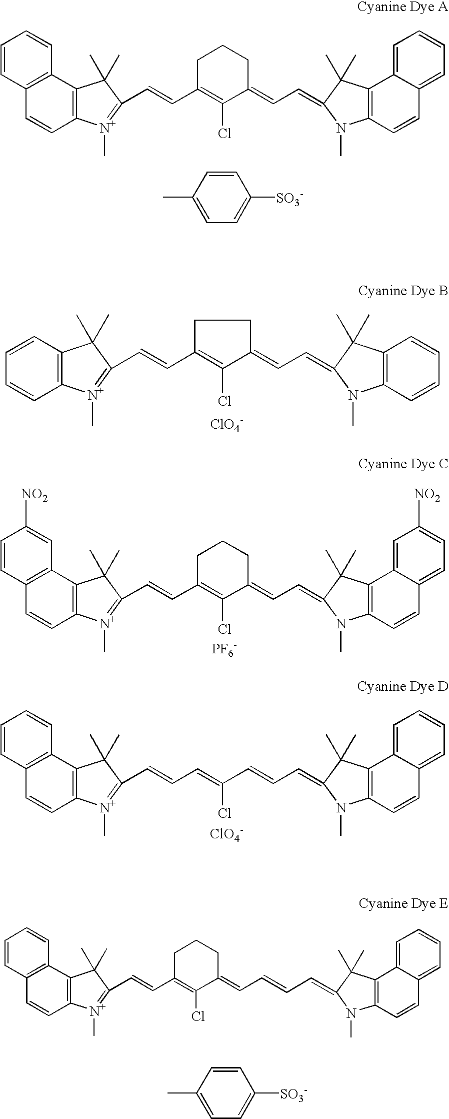
[Alkali-soluble Resin]

The alkali-soluble resin to be used in the image recording layer is a water-insoluble and alkali-soluble resin (hereinafter often referred to as “alkali-soluble high molecular compound”) and includes homopolymers containing an acid group in the principal chain and/or side chain in the polymer, copolymers thereof, and mixtures thereof. Accordingly, the image recording layer of the lithographic printing plate precursor has such a characteristic that when it comes into contact with the alkaline developer, it is dissolved therein.

As the alkali-soluble high molecular compound to be used in the image recording layer, ones which are conventionally known can be used without particular limitations, and high molecular compounds containing any one functional group of (1) a phenolic hydroxyl group, (2) a sulfonamide group, or (3) an active imido group. Examples thereof will be given below, but it should not be construed that the invention is limited thereto.
(1) Examples of the high molecular compound containing a phenolic hydroxyl group include novolak resins such as a phenol/formaldehyde resin, an m-cresol/formaldehyde resin, a p-cresol/formaldehyde resin, an m-/p-mixed cresol/formaldehyde resin, and a phenol/cresol (any of m-, p-, or m-/p-mixed cresol) mixed formaldehyde resin; and a pyrogallol/acetone resin. Besides, high molecular compounds containing a phenolic hydroxyl group in the side chain thereof are preferably used as the phenolic hydroxyl group-containing high molecular compound. Examples of the high molecular compound containing a phenolic hydroxyl group in the side chain thereof include high molecular compounds obtained by homopolymerizing a polymerizable monomer comprising a low molecular compound containing at least one of each of a phenolic hydroxyl group and a polymerizable unsaturated bond or copolymerizing such a polymerizable monomer with other polymerizable monomer.

Examples of the phenolic hydroxyl group-containing polymerizable monomer include acrylamides, methacrylamides, acrylic esters, methacrylic esters, and hydroxystyrenes, each containing a phenolic hydroxyl group. Specific examples thereof include N-(2-hydroxyphenyl)acrylamide, N-(3-hydroxyphenyl)acrylamide, N-(4-hydroxyphenyl)acrylamide, N-(2-hydroxyphenyl)methacrylamide, N-(3-hydroxyphenyl)methacrylamide, N-(4-hydroxyphenyl)methacrylamide, o-hydroxyphenyl acrylate, m-hydroxyphenyl acrylate, p-hydroxyphenyl acrylate, o-hydroxyphenyl methacrylate, m-hydroxyphenyl methacrylate, p-hydroxyphenyl methacrylate, o-hydroxystyrene, m-hydroxystyrene, p-hydroxystyrene, 2-(2-hydroxyphenyl)ethyl acrylate, 2-(3-hydroxyphenyl)ethyl acrylate, 2-(4-hydroxyphenyl)ethyl acrylate, 2-(2-hydroxyphenyl)ethyl methacrylate, 2-(3-hydrxoyphenyl)ethyl methacrylate, and 2-(4-hydroxyphenyl)ethyl methacrylate. The phenolic hydroxyl group-containing resin may be used in combinations of two or more kinds thereof Further, as described in U.S. Pat. No. 4,123,279, a copolymer of phenol containing an alkyl group having from 3 to 8 carbon atoms as a substituent and formaldehyde, such as a t-butylphenol/formaldehyde resin and an octylphenol/formaldehyde resin, may be used jointly.
(2) Examples of the alkali-soluble high molecular compound containing a sulfonamide group include high molecular compounds obtained by homopolymerizing a sulfonamide group-containing polymerizable monomer or copolymerizing such a polymerizable monomer with other polymerizable monomer. Examples of the sulfonamide group-containing polymerizable monomer include polymerizable monomers comprising a low molecular compound containing at least one of each of a sulfonamide group —NH—SO₂ in which at least one hydrogen atom is bonded on the nitrogen atom in one molecule thereof and a polymerizable unsaturated bond. Of these, low molecular compounds containing an acryloyl group, an allyl group or a vinyl group and a substituted or mono-substituted aminosulfonyl group or a substituted sulfonylimino group are preferable.
(3) As the alkali-soluble high molecular compound containing an active imido group, ones containing an active imido group in the molecule thereof are preferable. Examples of such a high molecular compound include high molecular compounds obtained by homopolymerizing a polymerizable monomer comprising a low molecular compound containing at least one of each of an active imido group and a polymerizable unsaturated bond in one molecule thereof or copolymerizing the polymerizable monomer with other polymerizable monomer.

Specifically, N-(p-toluenesulfonyl)methacrylamide and N-(p-toluenesulfonyl)acrylate can be preferably used as such a compound.

Further, high molecular compounds obtained by polymerizing two or more kinds of the foregoing phenolic hydroxyl group-containing polymerizable monomer, sulfonamide group-containing polymerizable monomer and active imido group-containing polymerizable monomer or high molecular compounds obtained by copolymerizing two or more kinds of these polymerizable monomers with other polymerizable monomer are preferably used as the alkali-soluble high molecular compound. In the case where the phenolic hydroxyl group-containing polymerizable monomer is copolymerized with the sulfonamide group-containing polymerizable monomer and/or the active imido group-containing polymerizable monomer, the compounding polymerization ratio (weight ratio) of these components preferably falls within the range of from 50/50 to 5/95, and especially preferably from 40/60 to 10/90.

In the case where the alkali-soluble high molecular compound is a copolymer of the foregoing phenolic hydroxyl group-containing polymerizable monomer, sulfonamide group-containing polymerizable monomer or active imido group-containing polymerizable monomer with other polymerizable monomer, in order that the alkali solubility may become sufficient, thereby sufficiently achieving an effect for enhancing the development latitude, the monomer for imparting the alkali solubility is preferably contained in an amount of 10% by mole or more, and more preferably 20% by mole or more.

As the monomer component to be copolymerized with the foregoing phenolic hydroxyl group-containing polymerizable monomer, sulfonamide group-containing polymerizable monomer or active imido group-containing polymerizable monomer, compounds listed in the following (m1) to (m12) can be enumerated. However, it should not be construed that the invention is limited thereto.

(m1) Acrylic esters or methacrylic esters containing an aliphatic hydroxyl group, such as 2-hydroxyethyl acrylate and 2-hydroxyethyl methacrylate.

(m2) Alkyl acrylates such as methyl acrylate, ethyl acrylate, propyl acrylate, butyl acrylate, amyl acrylate, hexyl acrylate, octyl acrylate, benzyl acrylate, 2-chloroethyl acrylate, and glycidyl acrylate.

(m3) Alkyl methacrylates such as methyl methacrylate, ethyl methacrylate, propyl methacrylate, butyl methacrylate, amyl methacrylate, hexyl methacrylate, cyclohexyl methacrylate, benzyl methacrylate, 2-chloroethyl methacrylate, and glycidyl methacrylate.

(m4) Acrylamides or methacrylamides such as acrylamide, methacrylamide, N-methylolacrylamide, N-ethylacrylamide, N-hexylmethacrylamide, N-cyclohexylacrylamide, N-hydroxyethylacrylamide, N-phenylacrylamide, N-nitrophenylacrylamide, and N-ethyl-N-phenylacrylamide.

(m5) Vinyl ethers such as ethyl vinyl ether, 2-chloroethyl vinyl ether, hydroxyethyl vinyl ether, propyl vinyl ether, butyl vinyl ether, octyl vinyl ether, and phenyl vinyl ether.

(m6) Vinyl esters such as vinyl acetate, vinyl chloroacetate, vinyl butyrate, and vinyl benzoate.

(m7) Styrenes such as styrene, α-methylstyrene, methylstyrene, and chloromethylstyrene.

(m8) Vinyl ketones such as methyl vinyl ketone, ethyl vinyl ketone, propyl vinyl ketone, and phenyl vinyl ketone.

(m9) Olefins such as ethylene, propylene, isobutylene, butadiene, and isoprene.

(m10) N-Vinylpyrrolidone, acrylonitrile, methacrylonitrile, etc.

(m11) Unsaturated imides such as maleimide, N-acryloylacrylamide, N-acetylmethacrylamide, N-propionylmethacrylamide, and N-(p-chlorobenzoyl)methacrylamide.

(m12) Unsaturated carboxylic acids such as acrylic acid, methacrylic acid, maleic anhydride, and itaconic acid.

Ones containing a phenolic hydroxyl group are preferable as the alkali-soluble high molecular compound from the standpoint of the matter that it is excellent in the image forming properties by exposure with infrared laser, etc. Preferred examples thereof include novolak resins such as a phenol/formaldehyde resin, an m-cresol/formaldehyde resin, a p-cresol/formaldehyde resin, an m-/p-mixed cresol/formaldehyde resin, and a phenol/cresol (any of m-, p-, or m-/p-mixed cresol) mixed formaldehyde resin; and a pyrogallol/acetone resin.

Also, examples of the alkali-soluble high molecular compound containing a phenolic hydroxyl group include polycondensates of a phenol containing an alkyl group having from 3 to 8 carbon atoms as a substituent and formaldehyde, such as a t-butylphenol/formaldehyde resin and an octylphenol/formaldehyde resin, as described in U.S. Pat. No. 4,123,279.

As the method of copolymerizing the alkali-soluble high molecular compound, a graft copolymerization method, a block copolymerization method, and a random copolymerization method, all of which are conventionally known, can be employed.

In the invention, in the case where the alkali-soluble high molecular compound is a homopolymer or copolymer of the foregoing phenolic hydroxyl group-containing polymerizable monomer, sulfonamide group-containing polymerizable monomer or active imido group-containing polymerizable monomer, ones having a weight average molecular weight of 2,000 or more and a number average molecular weight of 500 or more are preferable; and ones having a weight average molecular weight of from 5,000 to 300,000, a number average molecular weight of from 800 to 250,000, and a degree of dispersion (weight average molecular weight/number average molecular weight) of from 1.1 to 10 are more preferable.

Also, in the invention, in the case where the alkali-soluble high molecular compound is a resin such as a phenol/formaldehyde resin and a cresol/formaldehyde resin, ones having a weight average molecular weight of from 500 to 20,000 and a number average molecular weight of from 200 to 10,000 are preferable.

These alkali-soluble high molecular compounds may be used singly or in combinations of two or more kinds thereof. The alkali-soluble high molecular compound is used in the addition amount of from 30 to 99% by weight, preferably from 40 to 95% by weight, and especially preferably from 50 to 90% by weight in the whole of solids in the foregoing image forming layer. The foregoing range of the content is suitable from both the durability and the sensitivity of the image forming layer.

Also, the image forming layer may contain an alkali-soluble high molecular compound containing a carboxyl group (hereinafter often referred to as “component (B1)”).

Any alkali-soluble high molecular compounds containing a carboxyl group may be used as the high molecular compound as the component (B 1), but high molecular compounds (b1-1) and (b1-2) as defined below are preferable.

(b1-1) Alkali-soluble high molecular compound containing a polymerizable monomer unit represented by the following general formula (i) (hereinafter often referred to as “high molecular compound (b1-1)):

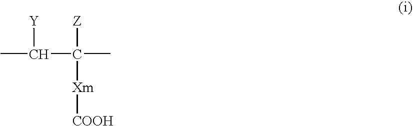

In the formula, Xm represents a single bond or a divalent connecting group; Y represents hydrogen or a carboxyl group; and Z represents hydrogen, an alkyl group, or a carboxyl group.

Examples of a monomer constituting the polymerizable monomer unit represented by the general formula (i) include polymerizable monomers containing at least one of each of a carboxyl group and a polymerizable unsaturated group in the molecule thereof

Specific examples of such a polymerizable monomer include α,β-unsaturated carboxylic acids such as acrylic acid, methacrylic acid, maleic acid, maleic anhydride, itaconic acid, and itaconic anhydride.

As a monomer to be copolymerized with the foregoing carboxyl group-containing polymerizable monomer, ones listed in the following (1) to (11) are enumerated, but it should not be construed that the invention is limited thereto.

(1) Aliphatic hydroxyl group-containing acrylic esters or methacrylic esters such as 2-hydroxyethyl acrylate and 2-hydroxyethyl methacrylate.

(2) Alkyl acrylates such as methyl acrylate, ethyl acrylate, propyl acrylate, butyl acrylate, amyl acrylate, hexyl acrylate, octyl acrylate, benzyl acrylate, 2-chloroethyl acrylate, glycidyl acrylate, and N-dimethylaminoethyl acrylate.

(3) Alkyl methacrylates such as methyl methacrylate, ethyl methacrylate, propyl methacrylate, butyl methacrylate, amyl methacrylate, hexyl methacrylate, cyclohexyl methacrylate, benzyl methacrylate, 2-chloroethyl methacrylate, glycidyl methacrylate, and N-dimethylaminoethyl methacrylate.

(4) Acrylamides or methacrylamides such as acrylamide, methacrylamide, N-methylolacrylamide, N-ethylacrylamide, N-hexylmethacrylamide, N-cyclohexylacrylamide, N-hydroxyethylacrylamide, N-phenylacrylamide, N-nitrophenylacrylamide, and N-ethyl-N-phenylacrylamide.

(5) Vinyl ethers such as ethyl vinyl ether, 2-chloroethyl vinyl ether, hydroxyethyl vinyl ether, propyl vinyl ether, butyl vinyl ether, octyl vinyl ether, and phenyl vinyl ether.

(6) Vinyl esters such as vinyl acetate, vinyl chloroacetate, vinyl butyrate, and vinyl benzoate.

(7) Styrenes such as styrene, α-methylstyrene, methylstyrene, and chloromethylstyrene.

(8) Vinyl ketones such as methyl vinyl ketone, ethyl vinyl ketone, propyl vinyl ketone, and phenyl vinyl ketone.

(9) Olefins such as ethylene, propylene, isobutylene, butadiene, and isoprene.

(10) N-Vinylpyrrolidone, N-vinylcarbazole, 4-vinylpyridine, acrylonitrile, methacrylonitrile, etc.

(11) Unsaturated imides such as maleimide, N-acryloylacrylamide, N-acetylmethacrylamide, N-propionylmethacrylamide, and N-(p-chlorobenzoyl)methacrylamide.

Also, a monomer represented by the following general formula (ii) is preferably used.

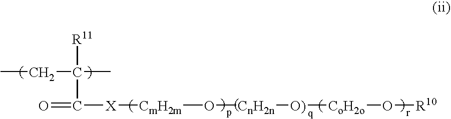

In the formula, X represents O, S, or N—R¹²; R¹⁰ to R¹² each independently represents a hydrogen atom or an alkyl group; m, n, and o each independently represents an integer of from 2 to 5; CₘH₂ₘ, CₙH₂ₙ, and CₒH₂ₒ may be each of a linear or branched structure; p, q, and r each independently represents an integer of from 0 to 3,000; and (p+q+r)≧2.

The alkyl group represented by R¹⁰ to R¹² is preferably one having from 1 to 12 carbon atoms, and specific examples thereof include a methyl group, an ethyl group, an n-propyl group, and an isopropyl group. p, q, and r each preferably represents an integer of from 0 to 500, and more preferably an integer of from 0 to 100.

Examples of monomers corresponding to the repeating unit represented by the foregoing general formula (ii) will be given below, but it should not be construed that the invention is limited thereto.

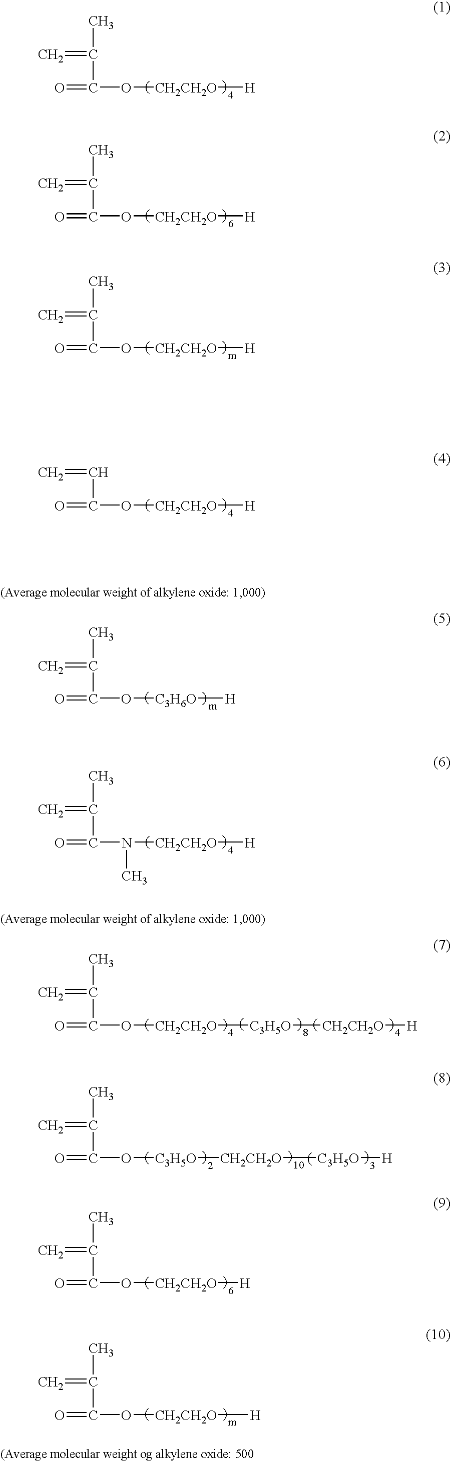

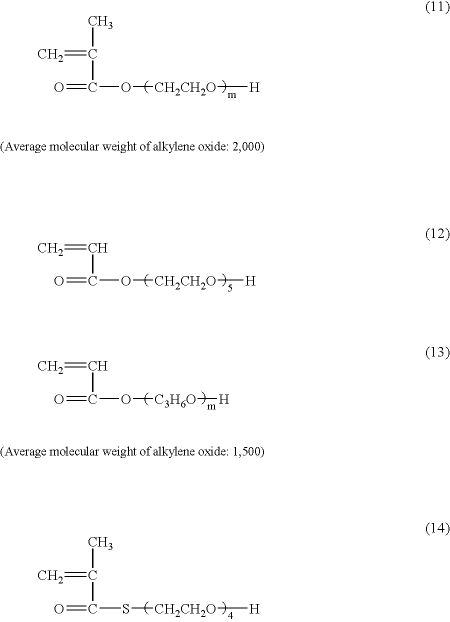

The repeating unit represented by the foregoing general formula (ii) can be produced by reacting a commercially available hydroxypoly(oxyalkylene) material (for example, trade names including Pluronic (manufactured by Asahi Denka Co., Ltd.), Adeka Polyether (manufactured by Asahi Denka Co., Ltd.), Carbowax (manufactured by Glycol Products Co.), Toriton (manufactured by Rohm and Haas Co.), and P.E.G. (manufactured by Dai-ichi Kogyo Seiyaku Co., Ltd.) with acrylic acid, methacrylic acid, acryl chloride, methacryl chloride, acrylic anhydride, etc. by a known method.

Separately, poly(oxyalkylene) diacrylates produced by known methods can also be used.

Examples of commercially available monomers include hydroxyl group-terminated polyalkylene glycol mono(meth)acrylates (for example, Blemmer PE-90, Blemmer PE-200, Blenmmer PE-350, Blemmer AE-90, Blemmer AE-200, Blemmer AE-400, Blemmer PP-1000, Blemmer PP-500, Blemmer PP-800, Blemmer AP-150, Blemmer AP-400, Blemmer AP-550, Blemmer AP-800, Blemmer 50PEP-300, Blemmer 70PEP-350B, Blemmer AEP Series, Blemmer 55PET-400, Blemmer 30PET-800, Blemmer 55PET-800, Blemmer AET Series, Blemmer 30PPT-800, Blemmer 50PPT-800, Blemmer 70PPT-800, Blemmer APT Series, Blemmer 10PPB-500B, and Blemmer 10APB-500B, all of which are manufactured by NOF Corporation); alkyl-terminated polyalkylene glycol mono(meth)acrylates (for example, Blemmer PME-100, Blemmer PME-200, Blemmer PME-400, Blemmer PME-1000, Blemmer PME-4000, Blemmer AME-400, Blemmer 50POEP-800B, Blemmer 50AOEP-800B, Blemmer PLE-200, Blemmer ALE-200, Blemmer ALE-800, Blemmer PSE-400, Blemmer PSE-1300, Blemmer ASEP Series, Blemmer PKEP Series, Blemmer AKEP Series, Blemmer ANE-300, Blemmer ANE-1300, Blemmer PNEP Series, Blemmer PNPE Series, Blemmer 43ANEP-500, and Blemmer 70ANEP-550, all of which are manufactured by NOF Corporation); and Light-Ester MC, Light-Ester 130MA, Light-Ester 041MA, Light-Acrylate BO-A, Light-Acrylate EC-A, Light-Acrylate MTG-A, Light-Acrylate 130A, Light-Acrylate DPM-A, Light-Acrylate P-200A, Light-Acrylate NP-4EA, and Light-Acrylate NP-8EA, all of which are manufactured by Kyoeisha Chemical Co., Ltd.

In the high molecular compound (b1-1), the minimum constitutional unit containing at least one of each of a carboxyl group and a polymerizable unsaturated group in the molecule thereof is not necessarily limited to one kind, but ones obtaining by copolymerizing two or more kinds of minimum constitutional units containing the same acid group or two or more kinds of minimum constitutional units containing a different acid group from each other can be used.

As the copolymerization method, a graft copolymerization method, a block copolymerization method, and a random copolymerization method, all of which are conventionally known, can be employed.

(b1-2) Alkali-soluble high molecular compound containing a carboxyl group and comprising as a basic skeleton a reaction product of a carboxyl group-containing diol compound represented by the following general formula (iii), (iv) or (v) and a diisocyanate compound represented by the following general formula (viii) (hereinafter often referred to as “high molecular compound (b1-2)).

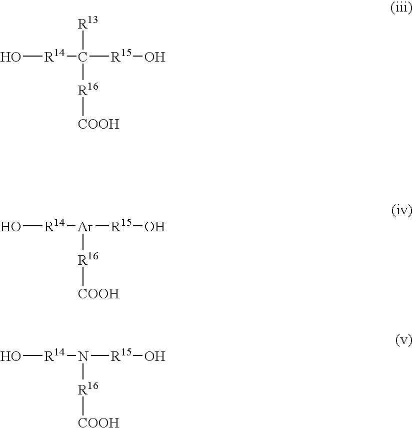

In the formula, R¹³ represents a hydrogen atom or an alkyl, alkenyl, aralkyl, aryl, alkoxy or aryloxy group which may have a substituent (for example, alkyl, aryl, alkoxy, ester, urethane, amide, ureido and halogeno groups are preferable); and preferably a hydrogen atom, an alkyl group having from 1 to 8 carbon atoms, an alkenyl group having from 2 to 8 carbon atoms, or an aryl group having from 6 to 15 carbon atoms.

R¹⁴, R¹⁵, and R¹⁶ may be the same or different and each represents a single bond or a divalent aliphatic or aromatic hydrocarbon which may have a substituent (for example, alkyl, alkenyl, aralkyl, aryl, alkoxy and halogeno groups are preferable); preferably an alkylene group having from 1 to 20 carbon atoms or an arylene group having from 6 to 15 carbon atoms; and more preferably an alkylene group having from 1 to 8 carbon atoms.

Also, if desired, R¹⁴, R¹⁵, and R¹⁶ may each contain other functional group which is not reactive with an isocyanate group, such as an ester group, a urethane group, an amide group, an ureido group, and a carbon-carbon unsaturated bond. Incidentally, two or three of R¹³, R¹⁴, R¹⁵, and R¹⁶ may be taken together to form a ring.

Ar represents an optionally substituted trivalent aromatic hydrocarbon group, and preferably an aromatic group having from 6 to 15 carbon atoms.
OCN—R¹⁸—NCO (viii)

In the formula, R¹⁸ represents a divalent aliphatic or aromatic hydrocarbon which may have a substituent (for example, alkyl, alkenyl, aralkyl, aryl, alkoxy and halogeno groups are preferable). If desired, R¹⁸ may contain other functional group which is not reactive with an isocyanate group, such as an ester group, a urethane group, an amide group, an ureido group, and a carbon-carbon unsaturated bond.

Specific examples of the carboxyl group-containing diol compound represented by the general formula (iii), (iv) or (v) include those described below.

That is, examples include 3,5-dihydroxybenzoic acid, 2,2-bis(hydroxymethyl)propionic acid, 2,2-bis(2-hydroxyethyl)propionic acid, 2,2-bis(3-hydroxypropyl)propionic acid, bis(hydroxymethyl)acetic acid, bis(4-hydroxyphenyl)acetic acid, 4,4-bis(4-hydroxyphenyl)pentanoic acid, tartaric acid, and N,N-bis(2-hydroxyethyl)-3-carboxypropionamide.

The carboxyl group-containing alkali-soluble high molecular compound (b1-2) is preferably a reaction product comprising a combination of diols represented by the following general formula (vi) or (vii).

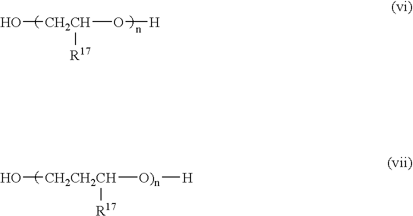

In the formulae, R¹⁷s each represents a hydrogen atom or an alkyl group having from 1 to 8 carbon atoms; and n represents an integer of 2 or more. Examples of the alkyl group having from 1 to 8 carbon atoms represented by R¹⁷ include a methyl group, an ethyl group, an isopropyl group, an n-butyl group, and an isobutyl group.

Specific examples of the diol represented by the foregoing general formula (vi) or (vii) will be given below, but it should not be construed that the invention is limited thereto.

Specific Examples of (vi)
HO—(—CH₂CH₂O—)₃—H
HO—(—CH₂CH₂O—)₄—H
HO—(—CH₂CH₂O—)₅—H
HO—(—CH₂CH₂O—)₆—H
HO—(—CH₂CH₂O—)₇—H
HO—(—CH₂CH₂O—)₈—H
HO—(—CH₂CH₂O—)₁₀—H
HO—(—CH₂CH₂O—)₁₂—H

Polyethylene glycol (average molecular weight: 1,000)

Polyethylene glycol (average molecular weight: 2,000)

Polyethylene glycol (average molecular weight: 4,000)
HO—(—CH₂CH(CH₃O)—)₃—H
HO—(—CH₂CH(CH₃O)—)₄—H
HO—(—CH₂CH(CH₃O)—)₆—H

Polypropylene glycol (average molecular weight: 1,000)

Polypropylene glycol (average molecular weight: 2,000)

Polypropylene glycol (average molecular weight: 4,000)

Specific Examples of (vii)
HO—(—CH₂CH₂CH₂O—)₃—H
HO—(—CH₂CH₂CH₂O—)₄—H
HO—(—CH₂CH₂CH₂O—)₈—H
HO—(—CH₂CH₂CH(CH₃)O—)₁₂—H

Specific examples of the diisocyanate compound represented by the general formula (viii) include those described below.

That is, examples include aromatic diisocyanate compounds (for example, 2,4-tolylene diisocyanate, a dimer of 2,4-tolylene diisocyanate, 2,6-tolylene diisocyanate, p-xylylene diisocyanate, m-xylylene diisocyanate, 4,4′-diphenylmethane diisocyanate, 1,5-naphthalene diisocyanate, and 3,3′-dimethylbiphenyl-4,4′-diisocyanate); aliphatic diisocyanate compounds (for example, hexamethylene diisocyanate, trimethylhexamethylene diisocyanate, lysine diisocyanate, and dimeric acid diisocyanate); and diisocyanate compounds as reaction products of a diol and a diisocyanate (for example, an adduct of one mole of 1,3-butylene glycol and two moles of tolylene diisocyanate).

The molar ratio of the diisocyanate to the diol compound, which are used in the synthesis of the high molecular compound (b1-2), is preferably from 0.8/1 to 1.2/1. In the case where an isocyanate group remains in the polymer terminal end, by treating with an alcohol or an amine, it is possible to synthesize the high molecular compound (b1-2) in the state where the isocyanate group does not ultimately remain.

The foregoing high molecular compounds (b1-1) and (b1-2) may be used singly or in combinations of two or more kinds thereof as the component (B1).

The content of the repeating unit containing the carboxyl group to be contained in the component (B1) is in the range of 2% by mole or more, preferably from 2 to 70% by moles, and more preferably from 5 to 60% by mole based on the total amount of the respective monomers of the component (B1).

The weight average molecular weight of the component (B1) is preferably from 3,000 to 300,000, and more preferably from 6,000 to 100,000.

Further, the addition amount of the component (B1) is in the range of from 0.005 to 80% by weight, preferably from 0.01 to 50% by weight, and more preferably from 1 to 20% by weight based on the weight of the whole of solids of the image recording layer.

[Additives]

In forming the foregoing image recording layer, in addition to the foregoing components, various additives can be added as the need arises so far as the effects of the invention are not hindered.

—Dissolution Inhibiting Compound—

In the lithographic printing plate precursor, for the purpose of enhancing that inhibition (dissolution inhibition), it is possible to contain a variety of inhibitors in the image recording layer layer.

The inhibitor is not particularly limited, and examples thereof include quaternary ammonium salts and polyethylene glycol based compounds.

The quaternary ammonium salt is not particularly limited, and examples thereof include tetraalkylammonium salts, trialkylarylammonium salts, dialkyldiarylammonium salts, alkyltriarylammonium salts, tetraarylammonium salts, cyclic ammonium salts, and dicyclic ammonium salts.

Specific examples include tetrabutylammonium bromide, tetrapentylammonium bromide, tetrahexylammonium bromide, tetraoctylammonium bromide, tetralaurylammonium bromide, tetraphenylammonium bromide, tetranaphthylammonium bromide, tetrabutylammonium chloride, tetrabutylammonium iodide, tetrastearylammonium bromide, lauryltrimethylammonium bromide, stearyltrimethylammonium bromide, behenyltrimethylammonium bromide, lauryltriethylammonium bromide, phenyltrimethylammonium bromide, 3-trifluoromethylphenyltrimethylammonium bromide, benzyltrimethylammonium bromide, dibenzyldimethylammonium bromide, distearyldimethylammonium bromide, tristearylmethylammonium bromide, benzyltriethylammonium bromide, hydroxyphenyltrimethylammonium bromide, and N-methylpyridinium bromide. Of these, quaternary ammonium salts described in Japanese Patent Application Nos. 2001-226297, 2001-370059 and 2001-398047.

The addition amount of the quaternary ammonium salt is preferably from 1 to 50% by weight, and more preferably from 1 to 30% by weight based on the amount of the whole of solids of the image recording layer. The foregoing range of the content is suitable from the standpoint of the matter that not only a sufficient dissolution inhibiting effect is revealed, but also the film forming properties of the binder do not become worse.

The polyethylene glycol based compound is not particularly limited, but the following structure is enumerated.
R¹—{—O—(R³—O—)ₘ—R²}ₙ

In the formula, R¹ represents a polyhydric alcohol residue or a polyhydric phenol residue; R² represents a hydrogen atom or an optionally substituted alkyl group, alkenyl group, alkynyl group, alkyloyl group, aryl group or aryloyl group having from 1 to 25 carbon atoms; R³ represents an optionally substituted alkylene group; m is 10 or more in average; and n represents an integer of from 1 to 4.

Examples of the polyethylene based compound having the foregoing structure include polyethylene glycols, polypropylene glycols, polyethylene glycol alkyl ethers, polypropylene glycol alkyl ethers, polyethylene glycol aryl ethers, polypropylene glycol aryl ethers, polyethylene glycol alkylaryl ethers, polypropylene glycol alkylaryl ethers, polyethylene glycol glycerin esters, polypropylene glycol glycerin esters, polyethylene sorbitol esters, polypropylene glycol sorbitol esters, polyethylene glycol fatty acid esters, polypropylene glycol fatty acid esters, polyethylene glycolated ethylenediamines, polypropylene glycolated ethylenediamines, polyethylene glycolated diethylenetriamines, and polypropylene glycolated diethylenetriamines.

Specific examples thereof include polyethylene glycol 1000, polyethylene glycol 2000, polyethylene glycol 4000, polyethylene glycol 10000, polyethylene glycol 20000, polyethylene glycol 50000, polyethylene glycol 100000, polyethylene glycol 200000, polyethylene glycol 500000, polypropylene glycol 1500, polypropylene glycol 3000, polypropylene glycol 4000, polyethylene glycol methyl ether, polyethylene glycol ethyl ether, polyethylene glycol phenyl ether, polyethylene glycol dimethyl ether, polyethylene glycol diethyl ether, polyethylene glycol diphenyl ether, polyethylene glycol lauryl ether, polyethylene glycol dilauryl ether, polyethylene glycol nonyl ether, polyethylene glycol cetyl ether, polyethylene glycol stearyl ether, polyethylene glycol distearyl ether, polyethylene glycol behenyl ether, polyethylene glycol dibehenyl ether, polypropylene glycol methyl ether, polypropylene glycol ethyl ether, polypropylene glycol phenyl ether, polypropylene glycol dimethyl ether, polypropylene glycol diethyl ether, polypropylene glycol diphenyl ether, polypropylene glycol lauryl ether, polypropylene glycol dilauryl ether, polypropylene glycol nonyl ether, polyethylene glycol acetyl ester, polyethylene glycol diacetyl ester, polyethylene glycol benzoic ester, polyethylene glycol lauryl ester, polyethylene glycol dilauryl ester, polyethylene glycol nonylic ester, polyethylene glycol cetylic ester, polyethylene glycol stearoyl ester, polyethylene glycol distearoyl ester, polyethylene glycol behenic ester, polyethylene glycol dibehenic ester, polypropylene glycol acetyl ester, polypropylene glycol diacetyl ester, polypropylene glycol benzoic ester, polypropylene glycol dibenzoic ester, polypropylene glycol lauric ester, polypropylene glycol dilauric ester, polypropylene glycol nonylic ester, polyethylene glycol glycerin ether, polypropylene glycol glycerin ester, polyethylene glycol sorbitol ether, polypropylene glycol sorbitol ether, polyethylene glycolated ethylenediamine, polypropylene glycolated ethylenediamine, polyethylene glycolated diethylenetriamine, polypropylene glycolated diethylenetriamine, and polyethylene glycolated pentamethylenehexamine.

The addition amount of the polyethylene glycol based compound is preferably from 0.1 to 50% by weight, and more preferably from 1 to 30% by weight based on the amount of the whole of solids of the image recording layer from the standpoints of revealing a sufficient dissolution inhibiting effect and keeping good image forming properties.

Also, in the case where a measure for the foregoing improvement of inhibition (dissolution inhibition) is taken, a lowering of the sensitivity is generated. In this case, it is effective to add a latone compound. It is considered that when the developer permeates into an exposed area, this lactone compound reacts with the developer to newly generate a carboxylic acid compound which contributes to the dissolution of the exposed area, thereby enhancing the sensitivity.

The lactone compound is not particularly limited, and examples thereof include compounds represented by the following general formulae (L-I) and (L-II).

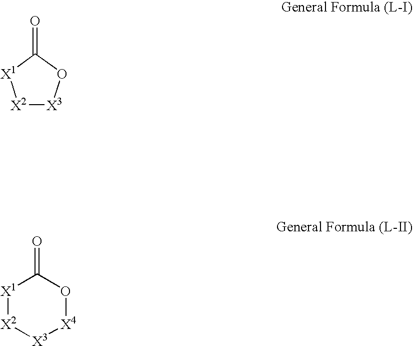

In the general formulae (L-I) and (L-II), X¹, X², X³ and X⁴, which may be the same or different, each represents a ring-constituting atom or atomic group and may each independently have a substituent. Each of at least one of X¹, X² and X³ in the general formula (L-I) and at least one of X¹, X², X³ and X⁴ in the general formula (L-II) has an electron withdrawing substituent or a substituent substituted with an electron withdrawing group.

The ring-constituting atom or atomic group represented by X¹, X², X³ and X⁴ is a non-metallic atom containing two single bonds for forming a ring or an atomic group containing the subject non-metallic atom.

The non-metallic atom or non-metallic atomic group is an atom or an atomic group selected among a methylene group, a sulfinyl group, a carbonyl group, a thiocarbonyl group, a sulfonyl group, a sulfur atom, an oxygen atom, and a selenium atom; and more preferably an atomic group selected among a methylene group, a carbonyl group, and a sulfonyl group.

Each of at least one of X¹, X² and X³ in the general formula (L-I) and at least one of X¹, X², X³ and X⁴ in the general formula (L-II) has an electron withdrawing substituent. In this specification, the electron withdrawing substituent refers to a group having a positive Hammett's substituent constant σp. With respect to the Hammett's substituent constant, Journal of Medicinal Chemistry, 1973, Vol. 16, No. 11, 1207-1216 can be made hereof by reference. Examples of the electron withdrawing group having a positive Hammett's substituent constant σup include halogen atoms (for example, a fluorine atom (σp value: 0.06), a chlorine atom (σp value: 0.23), a bromine atom (σp value: 0.23), and an iodine atom (σp value: 0.18)), trihaloalkyl groups (for example, triboromomethyl (σp value: 0.29), trichloromethyl (σp value: 0.33), and trifluoromethyl (σp value: 0.54)), a cyano group (σp value: 0.66), a nitro group (σp value: 0.78), aliphatic, aryl or heterocyclic sulfonyl groups (for example, methanesulfonyl (σp value: 0.72)), aliphatic, aryl or heterocyclic acyl groups (for example, acetyl (σp value: 0.50) and benzoyl (σp value: 0.43)), alkynyl groups (for example, C≡CH (σp value: 0.23)), aliphatic, aryl or heterocyclic oxycarbonyl groups (for example, methoxycarbonyl (σp value: 0.45) and phenoxycarbonyl (σp value: 0.44)), a carbamoyl group (σp value: 0.36), a sulfamoyl group (σp value: 0.57), a sulfoxide group, a heterocyclic group, an oxo group, and a phosphoryl group.

The electron withdrawing group is preferably a group selected among an amide group, an azo group, a fluoroalkyl group having from 1 to 5 carbon atoms, a nitrile group, an alkoxycarbonyl group having from 1 to 5 carbon atoms, an acyl group having from 1 to 5 carbon atoms, an alkylsulfonyl group having from 1 to 9 carbon atoms, an arylsulfonyl group having from 6 to 9 carbon atoms, an alkylsulfinyl group having from 1 to 9 carbon atoms, an arylsulfinyl group having from 6 to 9 carbon atoms, an arylcarbonyl group having from 6 to 9 carbon atoms, a thiocarbonyl group, a fluorine-containing alkyl group having from 1 to 9 carbon atoms, a fluorine-containing aryl group having from 6 to 9 carbon atoms, a fluorine-containing allyl group having from 3 to 9 carbon atoms, an oxo group, and a halogen element.

The electron withdrawing group is more preferably a group selected among a nitro group, a fluoroalkyl group having from 1 to 5 carbon atoms, a nitrile group, an alkoxycarbonyl group having from 1 to 5 carbon atoms, an acyl group having from 1 to 5 carbon atoms, an arylsulfonyl group having from 6 to 9 carbon atoms, an arylcarbonyl group having from 6 to 9 carbon atoms, an oxo group, and a halogen element.

Specific examples of the compounds represented by the general formulae (L-I) and (L-II) will be given below, but it should not be construed that the invention is limited thereto.

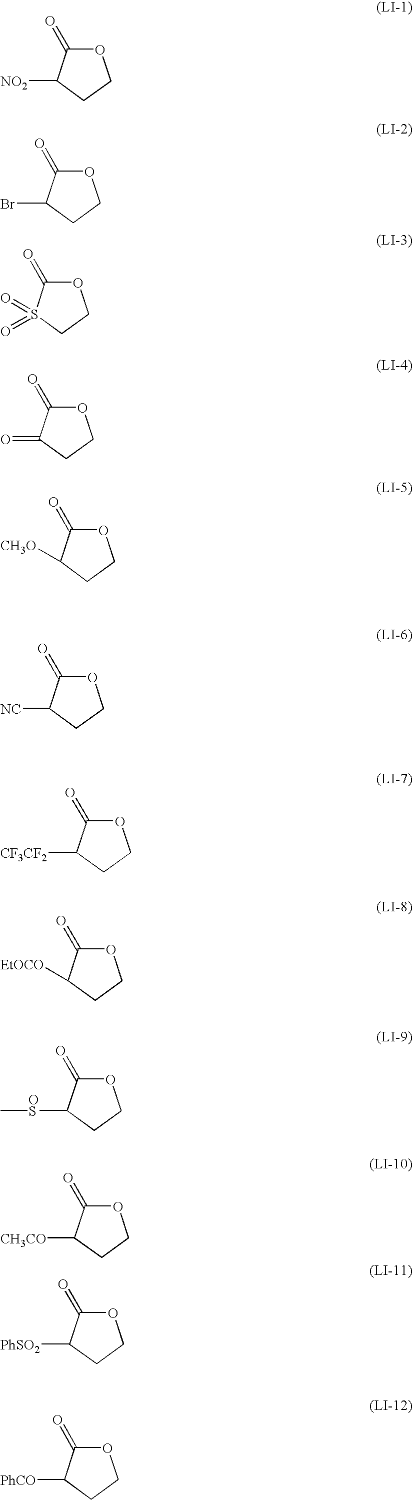

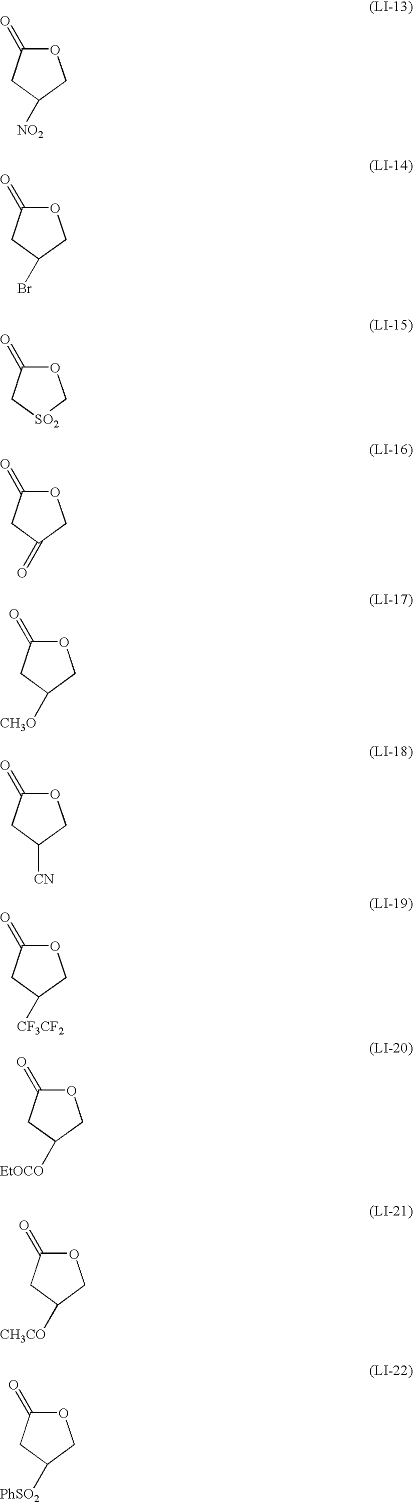

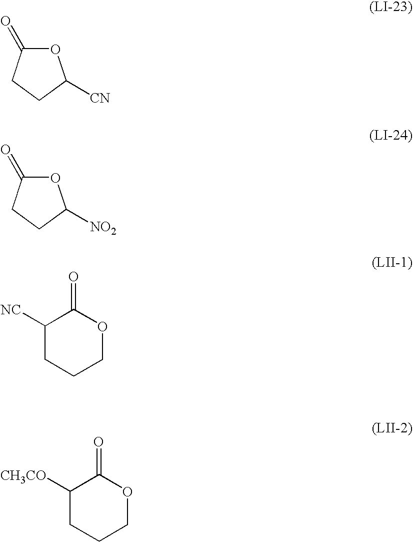

The addition amount of the compound represented by the general formula (L-I) or (L-II) is preferably from 0.1 to 50% by weight, and more preferably from 1 to 30% by weight based on the amount of the whole of solids of the image recording layer. Incidentally, since this compound reacts with the developer, it is desired to bring the compound into selective contact with the developer.

These lactone compounds can be used singly or jointly. Also, two or more kinds of the compounds of the general formula (L-I) or two or more kinds of the compounds of the general formula (L-II) may be used jointly in an arbitrary ratio within the foregoing range with respect to the total addition amount.

Also, for the purpose of enhancing the dissolution inhibition properties of the image area in the developer, it is preferred to use the compound together with a substance which is heat decomposable and which substantially lowers the solubility of the alkali-soluble high molecular compound in the non-decomposed state, such as onium salts, o-quinediazide compounds, aromatic sulfone compounds, and aromatic sulfonic ester compounds. Examples of the onium salt include diazonium salts, ammonium salts, phosphonium salts, iodonium salts, sulfonium salts, selenonium salts, and arsonium salts.

Preferred examples of the onium salt which is used in the invention include diazonium salts described in S. I. Schlensinger, Photogr. Sci. Eng., 18, 387 (1974), T. S. Bal, et al., Polymer, 21, 423 (1980), and JP-A-5-158230; ammonium salts described in U.S. Pat. Nos. 4,069,055 and 4,069,056 and JP-A-3-140140; phosphonium salts described in D. C. Necker, et al., Macromolecules, 17, 2468 (1984), C. S. Wen, et al., Teh. Proc. Conf. Rad. Curing ASIA, p.478. Tokyo, Oct. (1988), and U.S. Pat. Nos. 4,069,055 and 4,069,056; iodonium salts described in J. V. Crivello, et al., Macromolecules, 10(6), 1307 (1977), Chem. & Eng. News, Nov. 28, p.31 (1988), European Patent No. 104,143, U.S. Pat. Nos. 339,049 and 410,201, JP-A-2-150848, and JP-A-2-296514; sulfonium salts described in J. V. Crivello, et al., Polymer J., 17, 73 (1985), J. V. Crivello, et al., J. Org. Chem., 43, 3055 (1978), W. R. Watt, et al., J. Polymer Sci., Polymer Chem. Ed., 22, 1789 (1984), J. V. Crivello, et al., Polymer Bull., 14, 279 (1985), J. V. Crivello, et al., Macromolecules, 14(5), 1141 (1981), J. V. Crivello, et al., J. Polymer Sci., Polymer Chem. Ed., 17, 2877 (1979), European Patent Nos. 370,693, 233,567, 297,443 and 297,442, U.S. Pat. Nos. 4,933,377 and 3,902,114, U.S. Pat. Nos. 410,201 and 339,049, U.S. Pat. Nos. 4,760,013, 4,734,444 and 2,833,827, and German Patent Nos. 2,904,626, 3,604,580 and 3,604,581; selenonium salts described in J. V. Crivello, et al., Macromolecules, 10(6), 1307 (1977) and J. V. Crivello, et al., J. Polymer Sci., Polymer Chem. Ed., 17, 1047 (1979); and arsonium salts described in C. S. Wen, et al., Teh. Proc. Conf. Rad. Curing ASIA, p.478, Tokyo, October (1988).

Of the onium salts, diazonium salts are especially preferable. Also, as the preferred diazonium salt, those described in JP-A-5-158230 are enumerated.

Examples of counter ions against the onium salts include tetrafluoroboric acid, dexafluorophosphoric acid, triisopropylnaphthalenesulfonic acid, 5-nitro-o-toluenesulfonic acid, 5-sulfosalicylic acid, 2,5-dimethylbenzenesulfonic acid, 2,4,6-trimethylbenzenesulfonic acid, 2-nitrobenzenesulfonic acid, 3-chlorobenzenesulfonic acid, 3-bromobenzenesulfonic acid, 2-fluorocaprylnaphthalenesulfonic acid, dodecylbenzenesulfonic acid, 1-naphthol-5-sulfonic acid, 2-methoxy-4-hydroxy-5-benzoyl-benzenesulfonic acid, and p-toluenesulonic acid. Of these, hexafluorophosphoirc acid and alkyl aromatic sulfonic acids such as triisopropylnaphthalenesulfonic acid and 2,5-dimethylbenzenesulfonic acid are preferable.

As the preferred quinonediazides, o-quinonediazide compounds can be enumerated. The o-quinonediazide compound which is used in the invention is a compound containing at least one o-quinonediazide group, whose alkali solubility is increased upon heat decomposition, and compounds having a varied structure can be used. That is, the o-quinonediazide assists the solubility of the photographic system by both an effect that the dissolution inhibition of the binder is lost upon heat decomposition and an effect that the o-quinonediazide itself is converted into an alkali-soluble substance. As the o-quinonediazide compound to be used in the invention, compounds described on pages 339 to 352 of J. Kosar, Light-Sensitive Systems (John Wiley & Sons, Inc.) can be used. Especially, sulfonic esters or sulfonic amides of o-quinonediazide resulting from reaction with various aromatic polyhydroxy compounds or aromatic amino compounds are preferable. Also, an ester of benzoquinone-(1,2)-diazidosulfonic chloride or naphthoquinone-(1,2)-diazido-5-sulfonic chloride and a pyrogallol/acetone resin as described in JP-B-43-28403 and an ester of benzoquinone-(1,2)-diazidosulfonic chloride or naphthoquinone-(1,2)-diazido-5-sulfonic chloride and a phenol/formaldehyde resin as described in U.S. Pat. Nos. 3,046,120 and 3,188,210 can be preferably used.

Further, an ester of benzoquinone-(1,2)-diazidosulfonic chloride and a phenol-formaldehyde resin or a cresol/formaldehyde resin and an ester of or naphthoquinone-(1,2)-diazido-5-sulfonic chloride and a pyrogallol/acetone resin are similarly preferably used. Other useful o-quinonediazide compounds are reported and known in many patents. Examples thereof include those described in JP-A-47-5303, JP-A-48-63802, JP-A-48-63803, JP-A-48-96575, JP-A-49-38701, JP-A-48-13354, JP-B-41-11222, JP-B-45-9610, JP-B-49-17481, U.S. Pat. Nos. 2,797,213, 3,454,400, 3,544,323, 3,573,917, 3,674,495 and 3,785,825, British Patent Nos. 1,227,602, 1,251,345, 1,267,005, 1,329,888 and 1,330,932, and German Patent No. 854,890.

The addition amount of the o-quinonediazide compound is preferably in the range of from 1 to 50% by weight, more preferably from 5 to 30% by weight, and especially preferably from 10 to 30% by weight based on the whole of solids in the image recording layer. Such a compound can be used singly or may be used in admixture of several kinds thereof. Also, this compound may contain an alkali-soluble resin at a part of which is esterified, as described in JP-A-11-288089.

Also, for the purposes of reinforcing the dissolution inhibition of the surface of the image recoding layer and reinforcing the resistance to scratches on the surface, it is preferred to use jointly a polymer comprising as a polymerization component a (meth)acrylate monomer containing two or three perfluoroalkyl groups having from 3 to 20 carbon atoms in the molecule thereof as described in JP-A-2000-187318. With respect to the addition amount, its proportion in the whole of solids in the image recording layer is preferably from 0.1 to 10% by weight, and more preferably from 0.5 to 5% by weight.

—Development Promoter—

Also, for the purpose of further enhancing the sensitivity, it is possible to use jointly an acid anhydride, a phenol, or an organic acid.

As the acid anhydride, cyclic acid anhydrides are preferable. Specific examples thereof include phthalic anhydride, tetrahydrophthalic anhydride, hexahydrophthalic anhydride, 3,6-endoxy-tetrahydrophthalic anhydride, tetrachlorophtalic anhydride, maleic anhydride, chloromaleic anhydride, α-phenylmaleic anhydride, succinic anhydride, and pyromellitic anhydride as described in U.S. Pat. No. 4,115,128. As non-cyclic acid anhydrides, acetic anhydride and so on can be enumerated.

Examples of the phenol include bisphenol A, 2,2′-bishydroxysulfone, p-nitrophenol, p-ethoxyphenol, 2,4,4′-trihydroxybenzophenone, 2,3,4-trihydroxybenzophenone, 4-hydroxybenzophenone, 4,4′,4″-trihydroxytriphenylmethane, and 4,4′,3″,4″-tetrahydroxy-3,5,3′,5′-tetramethyltriphenylmethane.

Further, examples of the organic acid include sulfonic acids, sulfinic acids, alkylsulfuric acids, phosphonic acids, phosphoric esters, and carboxylic acids as described in JP-A-60-88942 and JP-A-2-96755. Specific examples thereof include p-toluenesulfonic acid, dodecylbenzenesulfonic acid, p-toluenesulfinic acid, ethyl sulfate, phenylphosphonic acid, phenylphosphinic acid, phenyl phosphate, diphenyl phosphate, benzoic acid, isophthalic acid, adipic acid, p-toluic acid, 3,4-dimethoxybenzoic acid, phthalic acid, terephthalic acid, 4-cyclohexene-1,2-dicarboxylic acid, erucic acid, lauric acid, n-undecanoic acid, and ascorbic acid.

The proportion of the foregoing acid anhydride, phenol or organic acid in the image recording layer is preferably from 0.05 to 20% by weight, more preferably from 0.1 to 15% by weight, and especially preferably from 0.1 to 10% by weight.

—Surfactant—

For the sake of improving the coating properties and broadening the processing stability against the development condition, it is possible to add a nonionic surfactant described in JP-A-62-251740 and JP-A-3-208514; an ampholytic surfactant described in JP-A-59-121044 and JP-A-4-13149; a siloxane based compound described in EP950517; or a fluorine-containing monomer copolymer described in JP-A-62-170950, JP-A-11-288093, and Japanese Patent Application No. 2001-247351 in the image recording layer.

Specific examples of the nonionic surfactant include sorbitan tristearate, sorbitan monopalmitate, sorbitan trioleate, stearic acid monoglyceride, and polyoxyethylene nonylphenyl ether. Examples of the ampholytic surfactant include an alkyl di(aminoethyl) glycine, an alkyl polyaminoethyl glycine hydrochloride, a 2-alkyl-N-carboxy-ethyl-N-hydroxyethyl imidazolium betaine, and an N-tetradecyl-N,N-betaine type (for example, a trade name “Amogen K”, manufactured by Dai-ichi Kogyo Seiyaku Co., Ltd.).

As the siloxane based compound, block copolymers of dimethylsiloxane and a polyalkylene oxide are preferable. Specific examples thereof include polyalkylene oxide-modified silicones such as DBE-224, DBE-621, DBE-712, DBP-732 and DBP-534, all of which are manufactured by Chisso Corporation; and Tego Glide 100, manufactured by Tego, Germany.

The proportion of the foregoing nonionic surfactant or ampholytic surfactant in the whole of solids in the image recording layer is preferably from 0.01 to 15% by weight, more preferably from 0.1 to 5% by weight, and more preferably from 0.05 to 0.5% by weight.

—Print-out Agent/Colorant—

A print-out agent for obtaining a visible image immediately after heating due to exposure and a dye or a pigment as an image colorant can be added in the image recording layer.

As the print-out agent, combinations of a compound which releases an acid by heating due to exposure (light acid releasing agent) with an organic dye capable of forming a salt can be enumerated as a representative example. Specific examples thereof include combinations of an o-naphthoqunonediazido-4-sulfonic acid halogenide with a salt forming organic dye described in JP-A-50-36209 and JP-A-53-8128; and combinations of a trihalomethyl compound with a salt forming organic dye described in JP-A-53-36223, JP-A-54-74728, JP-A-60-3626, JP-A-61-143748, JP-A-61-151644, and JP-A-63-58440. Examples of such a trihalomethyl compound include oxazole based compounds and triazine based compounds. All of these compounds are excellent in the stability due to aging and give clear print-out images.

As the colorant of image, other dyes than the foregoing salt forming organic dyes can be used. As preferred dyes including the salt forming organic dyes, oil-soluble dyes and basic dyes can be enumerated. Specific examples thereof include Oil Yellow #101, Oil Yellow #103, Oil Pink #312, Oil Green BG, Oil Blue BOS, Oil Blue #603, Oil Black BY, Oil Black BS, and Oil Black T-505 (all of which are manufactured by Orient Chemical Industries, Ltd.), Victoria Pure Blue, Crystal Violet Lactone, Crystal Violet (CI42555), Methyl Violet (CI42535), Ethyl Violet, Rhodamine B (CI145170B), Malachite Green (CI42000), and Methylene Blue (CI52015). Also, dyes described in JP-A-62-293247 are especially preferable.

Such a dye can be added in a proportion of from 0.01 to 10% by weight, and preferably from 0.1 to 3% by weight based on the whole of solids in the image recording layer in the printing plate material.

—Plasticizer—

If desired, in order to impart flexibility of the coating film, a plasticizer is added in the image recording layer. Examples thereof include butyl phthalyl, polyethylene glycol, tributyl citrate, diethyl phthalate, dibutyl phthalate, dihexyl phthalate, dioctyl phthalate, tricresyl phosphate, tributyl phosphate, trioctyl phosphate, tetrahydrofurfuryl oleate, and oligomers or polymers of acrylic acid or methacrylic acid.

—Waxing Agent—

For the purpose of imparting resistance against scratches, it is possible to add a compound which lowers a coefficient of static friction in the image recording layer of the lithographic printing plate precursor. Specifically, compounds containing an ester of a long chain alkylcarboxylic acid as used in U.S. Pat. No. 6,117,913 and Japanese Patent Application Nos. 2001-261627, 2002-032904 and 2002-165584 can be enumerated. With respect to the addition amount of such a compound, its proportion in the material which forms the layer is preferably from 0.1 to 10% by weight, and more preferably from 0.5 to 5% by weight.

The lithographic printing plate precursor can be usually produced by dissolving a heat-sensitive composition containing the foregoing respective components in a solvent and coating the solution on a suitable support.

[Coating Solvent]

Examples of the solvent which can be used include ethylene dichloride, cyclohexanone, methyl ethyl ketone, methanol, ethanol, propanol, ethylene glycol monomethyl ether, 1-methoxy-2-propanol, 2-methoxyethyl acetate, 1-methoxy-2-propyl acetate, dimethoxyethane, methyl lactate, ethyl lactate, N,N-dimethylacetamide, N,N-dimethylformamide, N-methylpyrrolidone, tetramethylurea, dimethyl sulfoxide, sulforane, γ-butyrolactone, toluene, and water. However, it should not be construed that the invention is limited thereto. These solvents are used singly or in admixture.

In choosing the coating solvent, with respect to a photosensitive lithographic printing plate having a two-layer structure of an upper recording layer and a lower recording layer, when the upper recording layer and the lower recording layer are provided adjacent to each other, in order to prevent compatibilization at the interface between the both layers, it is preferred to choose a coating solvent for the upper recording layer, which does not substantially dissolve the lower recording layer therein. The concentration of the foregoing components (the whole of solids including the additives) in the solvent is preferably from 1 to 50% by weight. In using an acid anhydride, it is preferable that the amount of water in the coating liquid is not more than 0.5%.

[Coating Amount]

Also, the coating amount (solids content) of the foregoing heat-sensitive composition varies depending upon the application and is suitably from 0.3 to 3.0 g/m², preferably from 0.5 to 2.5 g/m², and more preferably from 0.8 to 1.6 g/m² from the viewpoints of film characteristics and printing resistance.

[Laminated Structure]

In the lithographic printing plate precursor which is used in the invention, an image recording layer containing the foregoing components is provided on a support. The image recording layer may be a laminated construction having at least two layers (for the sake of convenience, the case comprising two layers of an upper layer and a lower layer will be hereinafter described).

In that case, as an alkali-soluble resin which constructs the upper layer and the lower layer, the alkali-soluble resin as described previously can be applied. It is preferable that the upper layer has lower solubility in alkalis than the lower layer.

Also, with respect to an infrared absorbing dye, the infrared absorbing dye may be different in the respective layers. Also, an infrared absorbing dye comprising plural compounds may be used in each layer. In all of the cases, the infrared absorbing dye can be added in a proportion of from 0.01 to 50% by weight, preferably from 0.1 to 50% by weight, and especially preferably from 0.1 to 30% by weight based on the whole of solids in the layer to which it is added. In the case where the infrared absorbing dye is added to plural layers, it is preferable that the total sum of the addition amounts falls within the foregoing range.

Since the foregoing substance which is heat decomposable and which substantially lowers the solubility of the alkali-soluble high molecular compound in the non-decomposed state may possibly be partially decomposed due to aging, in the case where the image recording layer is of a laminated construction, though it is effective to contain such a substance in the lower layer, the substance may be contained in any one of the layers or the both layers. The content of the substance is described previously. In the case where the substance is added in plural layers, it is preferable that the total sum of the addition amounts falls within the foregoing range.

Also, in the case of the laminated construction, though it is effective to contain a lactone compound in the lower layer, the lactone compound may be contained in any one of the layers or the both layers.

[Support]

As a hydrophilic support which is used in the lithographic printing plate precursor, dimensionally stable plate-like materials having necessary strength and durability can be employed. Examples thereof include papers, papers laminated with a plastic (for example, polyethylene, polypropylene, and polystyrene), metal plates (for example, aluminum, zinc, and copper), plastic films (for example, cellulose diacetate, cellulose triacetate, cellulose propionate, cellulose butyrate, cellulose acetobutyrate, cellulose nitrate, polyethylene terephthalate, polyethylene, polystyrene, polypropylene, polycarbonates, and polyvinyl acetal), and papers or plastic films laminated or vapor deposited with the foregoing metal.

A polyester film or an aluminum plate is preferable as the support. Of these, an aluminum plate which is dimensionally stable and comparatively cheap is especially preferable. As the aluminum plate, a pure aluminum plate, alloy plates containing aluminum as the principal component and containing a trace amount of foreign elements, and plastic films laminated or vapor deposited with aluminum are preferable. Examples of the foreign elements which are contained in the aluminum alloy include silicon, iron, manganese, copper, magnesium, chromium, zinc, bismuth, nickel, and titanium. The content of the foreign elements in the alloy is at most 10% by weight.

Although pure aluminum is especially preferable as the aluminum, since it is difficult to produce completely pure aluminum in view of the smelting technologies, ones containing a slight amount of foreign elements are employable. Such an aluminum plate is not specified with respect to its composition, aluminum plates made of raw materials which have hitherto been publicly known and used can be properly utilized. The thickness of the aluminum plate to be used in the invention is from approximately 0.1 mm to 0.6 mm, preferably from 0.15 mm to 0.4 mm, and especially preferably from 0.2 mm to 0.3 mm.

Prior to roughing the aluminum plate, for the purpose of removing a rolling oil on the surface, the aluminum plate is subjected to a degreasing treatment with, for example, a surfactant, an organic solvent, or an alkaline aqueous solution, if desired. The roughing treatment of the surface of the aluminum plate is carried out by carious methods, and examples thereof include a method of mechanically roughing the surface, a method of electrochemically dissolving and roughing the surface, and a method of chemically selectively dissolving the surface. As the mechanical method, known methods such as a ball polishing method, a brush polishing method, a blast polishing method, and a buff polishing method can be employed. Examples of the electrochemically roughing method include a method of roughing the surface in a hydrochloric acid or nitric acid electrolytic solution using an alternating current or a direct current. Also, a method comprising a combination of the both methods as disclosed in JP-A-54-63902 can be utilized.

If desired, the thus roughed aluminum plate is subjected to an alkali etching treatment or a neutralization treatment and then optionally subjected to an anodic oxidation treatment for the purpose of enhancing the water retention properties or abrasion resistance of the surface. As an electrolyte to be used in the anodic oxidation treatment of the aluminum plate, a variety of electrolytes which form a porous oxide film can be used. In general, sulfuric acid, phosphoric acid, oxalic acid, chromic acid, or a mixed acid thereof is used. The concentration of such an electrolyte is properly determined depending upon the type of the electrolyte.

The treatment condition of the anodic oxidation varies depending upon the electrolyte and therefore, cannot be unequivocally specified. However, in general, it is suitable that the concentration of the electrolyte is from 1 to 80% by weight of the solution, the liquid temperature is from 5 to 70° C., the current density is from 5 to 60 A/dm², the voltage is from 100 V, and the electrolysis time is in the range of from 10 seconds to 5 minutes. The amount of the anodically oxidized film is preferably 1.0 g/m² or more in view of the printing resistance. After the anodic oxidation treatment, the aluminum surface is subjected to a hydrophilization treatment, if desired. As the hydrophilization treatment, a method of using an alkali metal silicate (for example, a sodium silicate aqueous solution) as disclosed in U.S. Pat. Nos. 2,714,066, 3,181,461, 3,280,734 and 3,902,734 is employable. According to this method, the support is subjected to an immersion treatment or electrolytic treatment with a sodium silicate aqueous solution. Besides, a treatment method of using potassium fluorozirconate as disclosed in JP-B-36-22063 and a treatment method of using polyvinylphosphonic acid as disclosed in U.S. Pat. Nos. 3,276,868, 4,153,461 and 4,689,272 are employable.

Though the lithographic printing plate precursor which is used in the invention is one comprising a support having thereon at least the foregoing image recording layer, an undercoat layer can be provided between the support and the image recording layer as the need arises.

A variety of organic compounds are used as a component of the undercoat layer. Examples thereof include carboxymethyl cellulose, dextrin, gum arabic, amino group-containing phosphonic acid (for example, 2-aminoethylphosphonic acid), organic phosphonic acids (for example, optionally substituted phenylsulfonic acids, naphthylphosphonic acids, alkylphosphonic acids, glycerophosphonic acids, methylenediphosphonic acids and ethylenediphosphonic acids), organic phosphoric acids (for example, optionally substituted phenylphosphoric acids, naphthylphosphoric acids, alkylphosphoric acids, and glycerophosphoric acids), organic phosphinic acids (for example, optionally substituted phenylphosphinic acids, naphthylphosphinic acids, alkylphosphinic acids, and glycerophosphinic acids), amino acids (for example, glycine and β-alanine), and hydrochlorides of a hydroxyl group-containing amine (for example, a hydrochloride of triethanolamine). These organic compounds may be used in admixture of two or more kinds thereof

Further, an undercoat layer containing at least one kind of compounds selected from the group consisting of organic high molecular compounds having a structural unit represented by the following formula is also preferable.

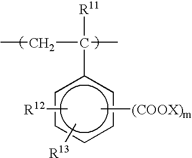

In the formula, R¹¹ represents a hydrogen atom, a halogen atom, or an alkyl group; R¹² and R¹³ each independently represents a hydrogen atom, a hydroxyl group, a halogen atom, an alkyl group, a substituted alkyl group, an aryl group, a substituted aryl group, —OR¹⁴, —COOR¹⁵, —CONHR¹⁶, —COR¹⁷, or —CN, or R¹² and R¹³ may be taken together to form a ring; R¹⁴ to R¹⁷ each independently represents an alkyl group or an aryl group; X represents a hydrogen atom, a metal atom, or NR¹⁸R¹⁹R²⁰R²¹; R¹⁸ to R²¹ each independently represents a hydrogen atom, an alkyl group, a substituted alkyl group, an aryl group, or a substituted aryl group, or R¹⁸ and R¹⁹ may be taken together to form a ring; and m represents an integer of from 1 to 3.

This undercoat layer can be provided by the following methods. That is, there are enumerated a method in which a solution of the foregoing organic compound dissolved in water or an organic solvent (for example, methanol, ethanol, and methyl ethyl ketone) or a mixed solvent thereof is coated on an aluminum plate and then dried to provide an undercoat layer; and a method in which an aluminum plate is immersed in a solution of the foregoing organic compound dissolved in water or an organic solvent (for example, methanol, ethanol, and methyl ethyl ketone) or a mixed solvent thereof to adsorb the foregoing compound and then washed with water, etc., followed by drying to provide an undercoat layer. In the former method, a solution of the foregoing organic compound in a concentration of from 0.005 to 10% by weight can be coated by various methods. Also, in the latter method, the concentration of the solution is from 0.01 to 20% by weight, and preferably from 0.05 to 5% by weight; the immersion temperature is from 20 to 90 ° C., and preferably from 25 to 50 ° C.; and the immersion time is from 0.1 seconds to 20 minutes, and preferably from 2 seconds to one minute. The solution to be used herein can be adjusted at a pH in the range of from 1 to 12 with a basic substance (for example, ammonia, triethylamine, and potassium hydroxide) or an acidic substance (for example, hydrochloric acid and phosphoric acid).

From the viewpoint of the sufficient printing resistance performance, the coating amount of the undercoat layer is suitably from 2 to 200 mg/m², and preferably from 5 to 100 mg/m².

The thus formed lithographic printing plate precursor is imagewise exposed and then subjected to development processing with the alkaline developer as described previously in detail.

Examples of a light source of the active rays to be used for the image exposure include a mercury vapor lamp, a metal halide lamp, a xenon lamp, a chemical lamp, and a carbon arc lamp. Examples of radiations include electron beams, X rays, ion beams, and far infrared light. Also, a g-line, an i-line, deep-UV light, and high-density energy beams (laser beams) are useful. Examples of the laser beams include helium-neon laser, argon laser, krypton laser, helium-cadmium laser, and KrF excimer laser. In the invention, light sources having an emitting wavelength in the region of from near infrared light to infrared light are preferable, and solid laser and semiconductor laser are especially preferable.

In the case where an unnecessary image area is present in the lithographic printing plated obtained by image exposure, development, water washing and/or rinse and/or gumming, erasing of that unnecessary image area is performed. For the erasing, for example, a method in which an erasing liquid as described in JP-B-2-13293 is coated on the unnecessary image area, allowed to stand as it is for a prescribed period of time, and then washed with water is preferable. A method described in JP-A-59-174842, in which the unnecessary image area is irradiated with active rays having been introduced by optical fibers and then developed, can be utilized.

The lithographic printing plate thus obtained according to the plate making method of the invention can be provided for the printing step after coating with a desensitized gum, if desired. In the case where it is intended to prepare a lithographic printing plate having a higher printing resistant force, a burning treatment is carried out. In the case where the lithographic printing plate is subjected to a burning treatment, it is preferred to treat the lithographic printing plate with a surface conditioning liquid as described in JP-B-61-2518, JP-B-55-28062, JP-A-1-31859, and JP-A-61-159655.

Examples of this method include a method of coating the surface conditioning liquid on the lithographic printing plate using a sponge or absorbent cotton infiltrated with a surface conditioning liquid, a method of coating the surface conditioning liquid on the lithographic printing plate upon immersion in a vat filled with the surface conditioning liquid, and a method of coating the surface conditioning liquid on the lithographic printing plate using an automatic coater. Also, after coating, by making the coating amount uniform using a squeegee or a squeegee roll, better results are given.

In general, the coating amount of the surface conditioning liquid is suitably from 0.03 to 0.8 g/m² (on a dry weight basis). If desired, after drying, the lithographic printing plate having a surface conditioning liquid coated thereon is heated at a high temperature using a burning processor (for example, a burning processor BP-1300, sold from Fuji Photo Film Co., Ltd.), etc. In this case, the heating temperature and time vary depending upon the types of the components which form the image, but it is preferable that the heating is carried out at a temperature in the range of from 180 to 300° C. for a time in the range of from 1 to 20 minutes.

The burning treated lithographic printing plate can be properly subjected to conventional treatments such as water washing and gumming as the need arises. In the case where a surface conditioning liquid containing a water-soluble high molecular compound, etc., is used, a so-called desensitization treatment such as gumming can be omitted. The thus treated and obtained lithographic printing plate is charged in an offset printing machine and used for printing multiple sheets.

<Embodiments of Treating Agent, Plate Material, etc.>

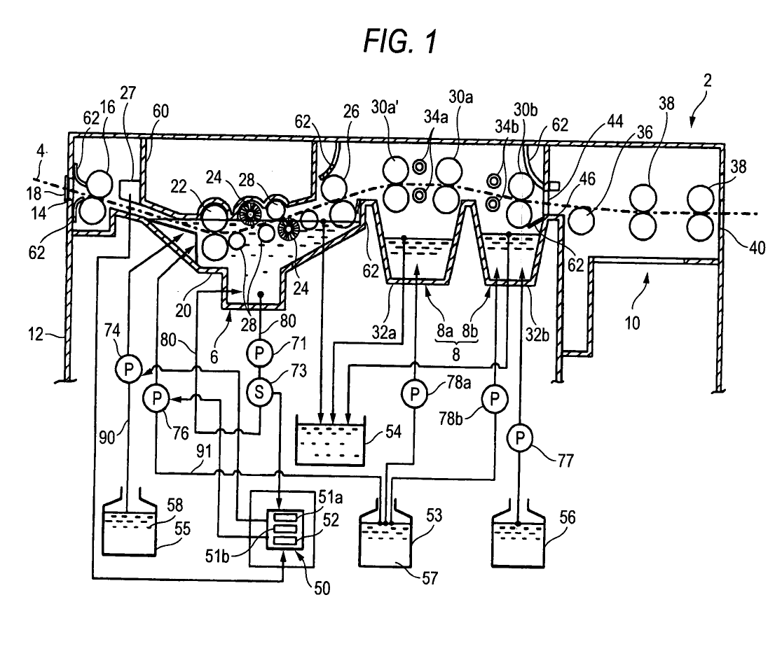

The invention will be described below with reference to the illustrated embodiments. FIG. 1 is a constructive view of the first embodiment of an automatic developing equipment for carrying out the development replenishing method according to the invention. As illustrated in FIG. 1, this automatic developing equipment 2 is provided with a developing section 6 for developing a photosensitive lithographic printing plate (hereinafter referred to as “PS plate”) 4, a post-processing section 8 for washing out a developer adhered on the developed PS plate 4 and coating a gum liquid, and a drying section 10 for drying the PS plate after coating with the gum liquid.

Also, in the case of processing the PS plate which requires heating before the development processing, a pre-heating section not illustrated in FIG. 1 can be provided. The pre-heating section is placed in the upstream side in the delivery direction of the developing section 6 and has a function to keep a specified surface temperature of the PS plate for a specified period of time while delivering the PS plate. The PS plate inserted in the pre-heating section is automatically delivered into a next step while being heated. Moreover, it is possible to provide a pre-water washing section not illustrated in FIG. 1. The pre-water washing section is placed in the upstream side in the delivery direction of the developing section 6 and in the downstream side in the delivery direction of the pre-heating section and has a function to wash the surface of the PS plate with washing water and cool it while delivering the PS plate. The PS plate inserted in the pre-water washing section is automatically delivered into the developing section 6 as a next step.

An insertion port 14 is formed in a side plate 12 of the automatic developing equipment 2, and the PS plate 4 inserted from the insertion port 14 is delivered into the developing section 6 by delivery rolls 16. The insertion port 14 is provided with a rubber blade 18, and when the PS plate 4 is not inserted, the insertion port 14 is closed by the rubber blade 18.

In a developing tan 20 of the developing section 6, delivery rolls 22, brush rolls 24, and squeeze rolls 26 are provided in this order from the upstream side in the delivery direction, and backup rolls 28 are provided in proper places therebetween. The PS plate 4 is immersed in the developer and subjected to development processing while being delivered by the delivery rolls 22.

The post-processing section 8 continued to the developing section 6 is constructed of a water washing section 8a and a finisher section 8b. The water washing section 8a is provided with rolls 30a′, 30a, each of which delivers the PS plate 4, a water washing tank 32a, and spray members 34a for spraying a washing liquid in the water washing tank 32a onto the PS plate 4. Further, the water washing section 8a is provided with a washing water feed pump 78a for feeding washing water into the water washing tank 32a. The finisher section 8b is provided with rolls 30b, each of which delivers the PS plate 4, a finisher tank 32b, and spray members 34b for spraying a finisher liquid in the finisher tank 32b. Further, the finisher section 8b is provided with a gum liquid feed pump 77 for feeding a gum liquid into the finisher tank 32b and a gum liquid dilute liquid feed pump 78b for feeding a gum liquid dilute liquid. The developed PS plate 4 is washed with water by spraying the washing water from the spray members 34a while being delivered by the delivery rolls 30a. Further, the PS plate 4 is coated by spraying the finisher liquid from the spraying members 34b while being delivered by the delivery rolls 30b.

At this time, the water washing tank 32a is replenished with a dilute liquid 57 in a replenishing dilute liquid storage tank 53 by the washing water feed pump 78a; and the finisher tank 32b is replenished with a gum liquid in a gum liquid tank 56 by the pump 77 and replenished with the dilute liquid 57 in the replenishing dilute liquid storage tank 53 by the replenishing liquid dilute liquid feed pump 78b. Here, the replenishing proportion of the gum liquid to the dilute liquid is, for example, 1/1. Following these replenishments, the washing water overflowed from the water washing tank 32a and the gum waste liquid overflowed from the finisher tank 32b are recovered in a waste liquid tank 54 in the same manner as in the development waste liquid.

Also, it is effective to provide the water washing section 8a with a water washing brush roll not illustrated in FIG. 1. This water washing rush roll is placed on the upper surface or upper and lower surfaces of the PS plate 4 between the spray members 34a and the PS plate 4 and rubs and water washes the surface of the delivered PS plate 4 while rotating.

On the other hand, a structure in which the water washing section 8a works as the first finisher section 8a and the finisher section 8b works as the second finisher section 8b is effective, too. The first finisher section 8a and the second finisher section 8b are provided with delivery rolls 30a, 30b for delivering the PS plate 4 and spray members 34a, 34b for spraying gum liquids in the finisher tanks 32a, 32b onto the PS plate 4. The developed PS plate 4 is coated by spraying the gum liquids from the spray members 34a, 34b while being delivered by the delivery rolls 30a, 30b. Incidentally, at this time, though the gum liquid in the finisher tank 32b of the second finisher section 8b located in the downstream side is overflowed and fed in the finisher tank 32a of the first finisher section 8a located in the upstream side, the gum liquid may be similarly fed by a pump, etc. instead of such a construction. In this case, the washing water feed pump 78a is not used.

At this time, the second finisher tank 32b is replenished with the gum liquid in the gum liquid tank 56 by the pump 77 and replenished with the dilute liquid 57 in the replenishing dilute liquid storage tank 53 by a replenishing liquid dilute liquid feed pump 78. Here, the replenishing proportion of the gum liquid to the dilute liquid is, for example, 1/1. Following this replenishment, the gum waste liquid overflowed from the first finisher tank 32a is recovered in the waste liquid tank 54 in the same manner as in the development waste liquid.

The drying section 10 continued to the finisher section 8 is provided with a guide roll 36 and a pair of tandem rolls 38 in this order from the upstream side in the delivery direction. Also, the drying section 10 is provided with a non-illustrated drying unit such as a warm air feed unit and a heat generating unit. The drying section 10 is provided with a discharge port 40, and the PS plate 4 which has been dried by the drying unit is discharged from the discharge port 40. Also, a shutter 44 is provided in a passage 46 between the drying section 10 and the finisher section 8, and when the PS plate 4 does not pass through the passage 46, the passage 46 is closed by the shutter 44.

A developing tank 20 is provided with a box-like shielding lid 60 integrated with the tank wall. The bottom wall of the shielding lid 60 is continuously curved in an arc form such that it does not come into contact with the upper peripheral surface of each of the delivery roll 22, the brush roll 24 and the backup roll 28, whereby it does not interfere with the rolls, etc. Since the shielding lid 60 is formed in the box-like shape, an airtight space is formed in the upper portion of the developing tank 20, whereby the air amount in the developing section 6 is made small as far as possible. Also, by providing the shielding lid 60, the contact area between the developer and air is made small as far as possible.

The automatic developing equipment 2 having the foregoing construction is provided with rubber blades 62 in proper places, and a portion extending from the developing section 6 to the finisher section 8b is constructed substantially airtight against the outer circumference, whereby external air does not flow thereinto. Also, a portion extending from the developing section 6 to the water washing section 8a is constructed substantially airtight by the rubber blades 62, whereby the air in the water washing section 8a does not flow into the developing section 6. Accordingly, though when the PS plate 4 passes through the developing section 6, the air slightly flows thereinto, the development section 6 is substantially airtight and is of a sealing type construction such that air does not substantially flow thereinto.

Next, the developing section 6 will be described below in detail. The developing tank 20 is connected with a circulating conduit 80 for the developer. The circulating conduit 80 is provided with a circulating pump 71 for the developer, an electric conductivity sensor 73, and a filter (not illustrated). The circulating pump 71 for the developer sucks the developer in the developing tank 20 into circulating conduit 80 from a suction hole provided in the bottom of the developing tank 20, circulates the developer in the circulating conduit 80, and then again discharges it into the developing tank 20. The foregoing filter filters the developer flowing in the circulating conduit 80. The foregoing electric conductivity sensor 73 measures the electric conductivity of the developer flowing in the circulating conduit 80.

Also, the developing section 6 is provided with replenishing conduits 90, 91, a replenishing stock liquid storage tank 55 connected to the replenishing conduit 90, a replenishing stock liquid feed pump 74 included in the replenishing conduit 90, a replenishing dilute liquid storage tank 53 connected to the replenishing conduit 91, and a replenishing dilute liquid feed pump 76 included in the replenishing conduit 91, each of which constructs the replenishing device, and they function as units for replenishing the developer. Also, the development waste liquid overflowed from the developing tank 20 is recovered in the waste liquid tank 54.

Specifically, a pair of the replenishing conduits 90, 91 of a development replenisher obtained by diluting a development replenisher stock liquid 58 with a replenishing dilute liquid 57 are provided in the vicinity of the foregoing developing tank 20. In the replenishing conduit 90 of the development replenisher stock liquid 58, its other end (the lower end in FIG. 1) is connected to the replenishing stock liquid storage tank 55, and the replenishing stock liquid feed pump 74 is provided in the conduit. The replenishing stock liquid feed pump 74 feeds the development replenisher stock liquid 58 into the developing tank 20 from the replenishing stock liquid storage tank 55. In the replenishing conduit 91 of the replenishing dilute liquid 57, its other end (the lower end in FIG. 1) is connected to the replenishing dilute liquid storage tank 53, and the replenishing dilute liquid feed pump 76 is provided in the conduit. The replenishing dilute liquid feed pump 76 feeds the replenishing dilute liquid (water) 57 into the developing tank 20 from the replenishing dilute liquid storage tank 53. That is, the dilute liquid replenishing device is constructed of the replenishing conduit 91, the replenishing dilute liquid feed pump 76, and the replenishing dilute liquid storage tank 53.

The foregoing replenishing stock liquid feed pump 74 and replenishing dilute liquid feed pump 76 are controlled by a control device (control unit) 50 provided with a control ROM 51a or a control RAM 51b as condition storing means based on signals from the electric conductivity sensor 73 and a time measuring section 52. Also, the control device 50 actuates the delivery rolls 22, the brush rolls 24, the squeeze rolls 26, and the like at proper timing based on a signal from a plate detecting sensor 27, to deliver the PS plate.

Further, in the control device 50, the time measuring section 52 measures an elapsed time from a point in time of the last integration of replenishment due to aging and an elapsed time from a point in time of the last measurement of electric conductivity, and the electric conductivity of the developer is measured by the electric conductivity sensor 73. If necessary, the control device 50 feeds a development replenisher (the development replenisher stock liquid 58 and the replenishing dilute liquid 57) into the developing tank 20 from the replenishing stock liquid storage tank 55 and the replenishing dilute liquid storage tank 53 at predetermined replenishing amount and replenisher diluting rate while utilizing these values.

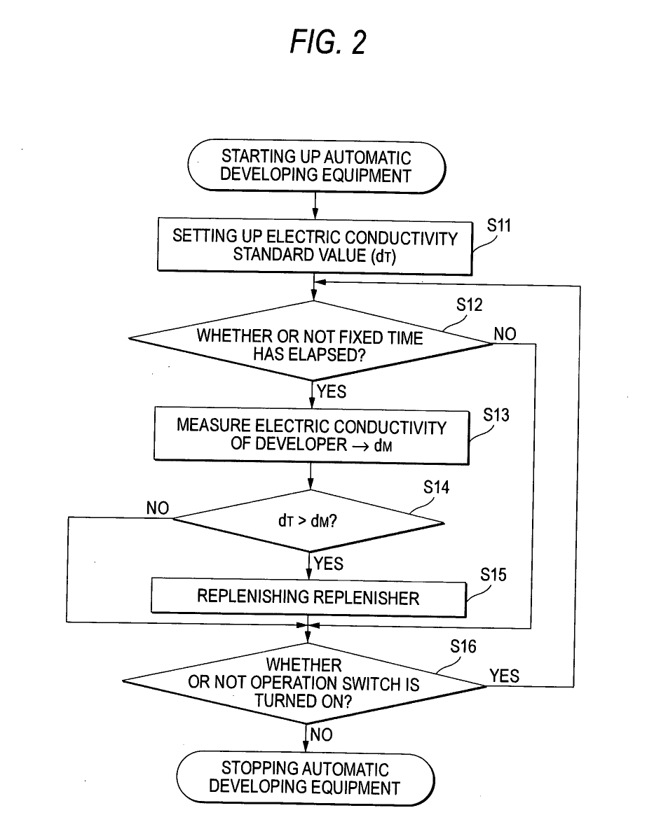

Next, the control by the control device 50 will be described below. FIGS. 2, 3, 4 and 5 are each an example of a flow chart exhibiting the control system by the control device 50. According to these control systems, even when the processing conditions such as the type of plate, the size of plate, and the processing frequency are changed, it is possible to carry out the replenishment based on a proper replenishing amount.

First of all, the basic control processing for replenishing the development replenisher will be described below with reference to FIG. 2.

After star-up of the automatic developing equipment, in step 11 (hereinafter abbreviated as “S11”), an electric conductivity value of the developer at which an empirically predetermined activity of the developer becomes proper is set up at an electric conductivity standard value (d_{T}). Next, in S12, whether the elapsed time from the start-up time or a point of time of the last measurement of electric conductivity of the developer has reached a predetermined fixed time is judged, and when the elapsed time has reached, the control goes to S13, whereas when the elapsed time has not reached, the control goes to S16.

In S13, the electric conductivity of the developer is measured. Next, in S14, the measured electric conductivity value (d_{M}) of the developer is compared with the electric conductivity standard value (d_{T}), and when the measured electric conductivity value (d_{M}) of the developer is smaller than the electric conductivity standard value (d_{T}), the control goes to S15, whereas when the measured electric conductivity value (d_{M}) of the developer is not smaller than the electric conductivity standard value (d_{T}), the control goes to S16.

In S15, a predetermined amount of the replenisher is replenished in the developer, and the control goes to S16.

In S16, the state of an operation switch of the automatic developing equipment is examined, and when the operation switch is turned on, the control returns to S12, whereas when the operation switch is turned off, the processing is ended by stopping of the device.

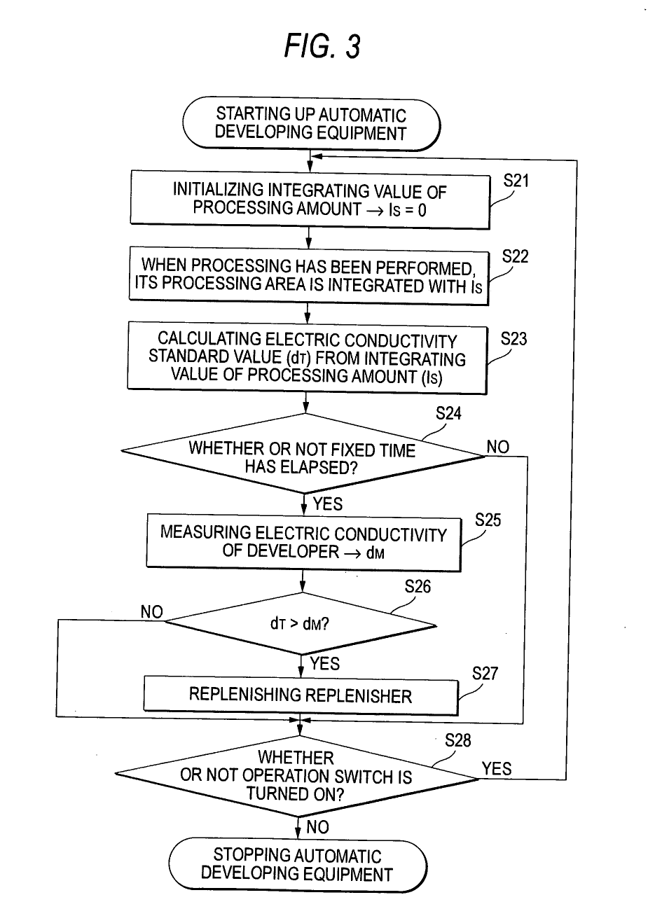

Next, the first control processing which specifically shows the foregoing basic control processing will be described below with reference to FIG. 3.

In this control processing, an electric conductivity value operated from the total processing amount of the photosensitive lithographic printing plate having been processed with the developer is used as the electric conductivity standard value.

In S21, an integrating value of processing amount which is a variable to be used during the control is initialized, i.e., 0 is substituted.

In S22, when the processing has been performed, its processing area is integrated with I_{S}. Next, in S23, the electric conductivity standard value (d_{T}) is calculated from this I_{S} according to an operation expression. For example, the following expression is desired as the operation expression to be used at this time.
d_{T}=(D_{M}−D_{L})×EXP(−C₁×I_{S})+D_{L} Operation Expression 1

In the expression, D_{M}, D_{L} and C₁ each represents an empirically predetermined constant; and EXP(x)=e^{x}.

Next, in S24, whether the elapsed time from the start-up time or a point in time of the last measurement of electric conductivity of the developer has reached a predetermined time is judged, and when the elapsed time has reached, the control goes to S25, whereas when the elapsed time has not reached, the control goes to S28.

In S25, an electric conductivity of the developer is measured, and its value is substituted for a variable (d_{M}). In next S26, d_{M} is compared with d_{T}, and when d_{M} is smaller than d_{T}, the control goes to S27, whereas when d_{M} is not smaller than d_{T}, the control goes to S28. In S27, a predetermined amount of the replenisher is replenished in the developer.

In S28, the state of an operation switch of the automatic developing equipment is examined, and when the operation switch is turned on, the control returns to S22, whereas when the operation switch is turned off, the processing is ended by stopping of the device.

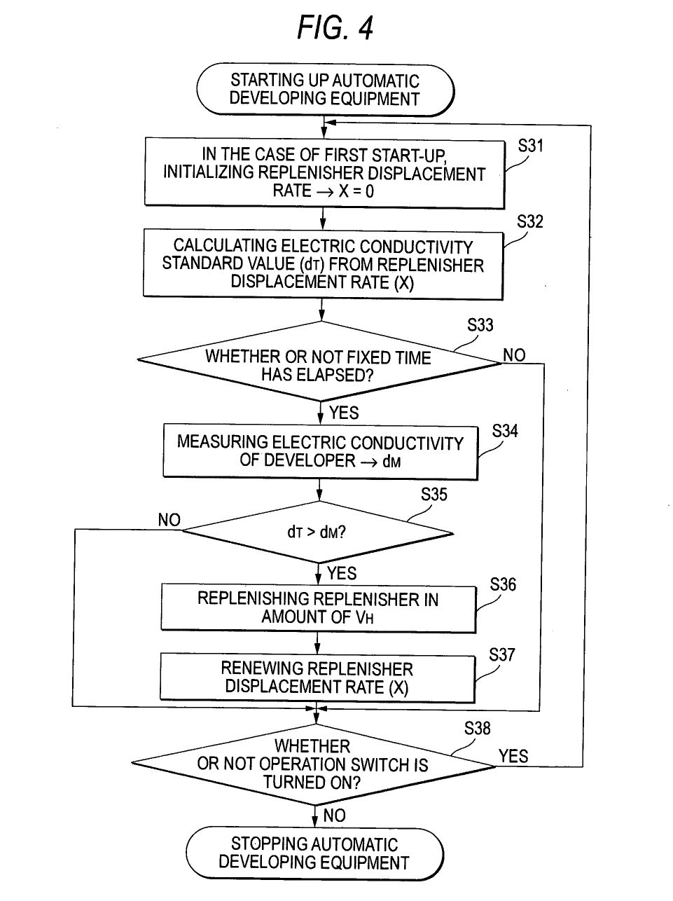

Next, the second control processing will be described below with reference to FIG. 4.

In this control processing, an electric conductivity value operated from replenisher displacement rate which is a rate of the development replenisher replenished in the developer in the developer is used as the electric conductivity standard value.

First of all, in S31, whether or not this automatic developing equipment is first started up is judged, and in the case of the first start-up, replenisher displacement rate (X) which is a variable to be used during the control is initialized, i.e., 0 is substituted for X.

In S32, the electric conductivity standard value (d_{T}) is calculated from X according to an operation expression. For example, the following expression is desired as the operation expression to be used at this time.
d_{T}=(1−X)×d_{M}+X×d_{L} Operation Expression 2

In the expression, d_{M} and d_{L} each represents an empirically predetermined constant.

Next, in S33, whether the elapsed time from the start-up time or a point in time of the last measurement of electric conductivity of the developer has reached a predetermined time is judged, and when the elapsed time has reached, the control goes to S34, whereas when the elapsed time has not reached, the control goes to S38.

In S34, an electric conductivity of the developer is measured, and its value is substituted for a variable (d_{M}). In next S35, d_{M} is compared with d_{T}, and when d_{M} is smaller than d_{T}, the control goes to S36, whereas when d_{M} is not smaller than d_{T}, the control goes to S38. In S36, a predetermined amount (V_{H}) of the replenisher is replenished in the developer, and in next S37, X is renewed using V_{H} and an operation expression. For example, the following expression is desired as the operation expression to be used at this time.
X=(V_{T}×X₀+V_{H})÷(V_{T}+V_{H}) Operation Expression 3

In the expression, X₀ represents a value of the rate of displacement of replenisher before the renewal; and V_{T} represents a volume of the developer in the developing tank.

In S38, the state of an operation switch of the automatic developing equipment is examined, and when the operation switch is turned on, the control returns to S32, whereas when the operation switch is turned off, the processing is ended by stopping of the device.

Next, the third control processing will be described below with reference to FIG. 4.

In this control processing, an electric conductivity value operated from a replenishing rate due to aging which is a rate of an amount of replenisher due to aging operated from an operation time and a stopping time of the automatic developing equipment of photosensitive lithographic printing plate to the total replenishing amount and replenisher displacement rate which is a rate of the development replenisher replenished in the developer in the developer is used as the electric conductivity standard value.

In S41, an integrating value of replenishment due to aging (I_{C}) which is a variable to be used during the control is initialized, i.e., 0 is substituted. Also, whether this automatic developing equipment is first started up, and in the case of the first start-up, replenisher displacement rate (X) and a rate of replenishment due to aging (F), both of which are a variable to be used during the control, are initialized, i.e., 0 is substituted for X, and a predetermined constant (C_{F}) is substituted for F.

In S42, a replenishing amount due to aging corresponding to a stopping time (T_{F}) of the automatic developing equipment is integrated with I_{C}. For example, the operation is carried out according to the following expression.
I_{C}+V_{F}×T_{F}→I_{C} Operation Expression 4

In the expression, V_{F} is an empirically predetermined constant.

In S43, whether the elapsed time from the start-up time or a point of time of the last integration of replenishing amount due to aging has reached a predetermined time (T_{K}) is judged, and when the elapsed time has reached, the control goes to S44, whereas when the elapsed time has not reached, the control goes to S45.

In S44, the replenishing amount due to aging which becomes necessary at the elapsed time (T_{K}) is integrated with I_{C}. For example, the operation is carried out according to the following expression.
I_{C}+V_{N}×T_{K}→I_{C} Operation Expression 5

In the expression, V_{N} is an empirically predetermined constant.

In S45, the electric conductivity standard value (d_{T}) is calculated from the values of X and F according to an operation expression. For example, the following expression is desired as the operation expression to be used at this time.
d_{T}=(1−X)×D_{M}+X×((1−F)×D_{B}÷F×D_{C}) Operation Expression 6

In the expression, D_{M}, D_{D} and D_{C} each represents an empirically predetermined constant.

Next, in S46, whether the elapsed time from the start-up time or a point in time of the last measurement of electric conductivity of the developer has reached a predetermined time (T_{D}) is judged, and when the elapsed time has reached, the control goes to S47, whereas when the elapsed time has not reached, the control goes to S52.

In S47, an electric conductivity of the developer is measured, and its value is substituted for a variable (d_{M}). In next S48, the measured electric conductivity value (d_{M}) of the developer is compared with the electric conductivity standard value (d_{T}), and when d_{M} is smaller than d_{T}, the control goes to S49, whereas when dm is not smaller than d_{T}, the control goes to S52.

In S49, a predetermined amount (V_{H}) of the replenisher is replenished in the developer.

Further, in next S50, the values of X and F are renewed by the values of I_{C} and V_{H}. For example, the renewal of the values is suitably carried out according to the following expressions.
(V_{T}×X+V_{H})÷(V_{T}+V_{H})→X Operation Expression 7
(V_{T}×X×F+I_{C})÷(V_{T×X+V}_{H})→F Operation Expression 8

In the expressions, V_{T} represents a volume of the developer in the developing tank.

Also, in next S51, I_{C} is initialized, i.e., 0 is substituted therein.

In S52, the state of an operation switch of the automatic developing equipment is examined, and when the operation switch is turned on, the control returns to S43, whereas when the operation switch is turned off, the processing is ended by stopping of the device.

According to the foregoing control of the automatic developing equipment, by utilizing the value of electric conductivity of the developer, even when the type, size and processing frequency of the photosensitive material are changed, it is possible to always carry out proper replenishment and to carry out the development processing at a stable and fixed sensitivity. Therefore, it is possible to minimize the fluctuation in sensitivity of the developer against the changes of the development processing condition while employing a simple and cheap constructions in the developing section of the automatic developing equipment.

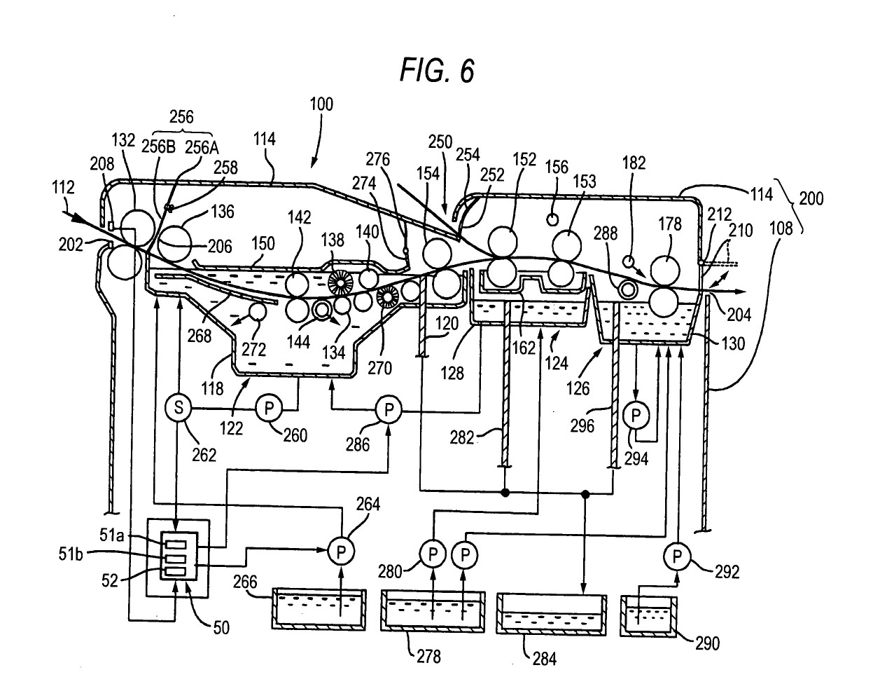

Next, the second embodiment of the invention will be described below. FIG. 6 is a constructive view of an automatic developing equipment according to the second embodiment of the invention. As illustrated in FIG. 6, in an automatic developing equipment 100, an internal processing section is covered by an outside panel 114. A developing section 122 provided with a developing tank 118 for developing a PS plate 112 and an overflow pipe 120 for recovering a developer overflowed from the developing tank 118; a water washing section 124 for water washing the developer adhered to the PS plate 112; and a finisher section 126 for coating a gum liquid on the PS plate 112 after water washing to desensitize it are provided inside the outside panel 114. Incidentally, a water washing tank 128 is provided in the water washing section 124, and a gum liquid tank 130 is provided in the finisher section 126.

The outside panel 114 is provided with a slit-form insertion port 202 and a discharge port 204, respectively. An insertion port (sub-insertion port) 250 for reentry from which the PS plate 112 is inserted between the developing section 122 and the water washing section 124 is provided on the top face of the outside panel 114. This sub-insertion port 250 functions as an insertion port of the PS plate 112 for carrying out the processing exclusive of the development processing.

This sub-insertion port 250 is provided with a blade 252. In the blade 252, its tip portion is brought into contact with the outside panel 114 functioning as a guiding support face of the sub-insertion port 250, and its base portion is fixed to the back side of the outside panel 114 via a bracket 254. Thus, the sub-insertion port 250 is in the closed state by the blade 252.

In a drying section (not illustrated), while delivering the PS plate 112 sent out from the finisher section 126 by a number of non-illustrated rolls, warm air is blown onto the both surfaces of this PS plate 112 to dry the PS plate 112.

A pair of delivery rolls 132 are provided in the insertion side of the PS plate 112 into the developing tank 118 of the developing section 122, and the PS plate 112 is inserted between the pair of delivery rolls 132 from the insertion port 202.

A rubber blade 206 is installed in the vicinity of the downstream side of the delivery rolls 132. In the blade 206, its tip portion is brought into contact with the side wall of the developing tank 118 of the developing section 122, and its base portion is installed in the outside panel 114 via the bracket 256. The bracket 256 is constructed of a fixing portion 256A and a slide portion 256B installed in the fixing portion by a butterfly screw 258, and the blade 206 is fixed to the slide portion 256B. Thus, the blade 206 is constructed in such a manner that by loosing the butterfly screw 258 to slide the slide portion 256B against the fixing portion 256A, the tip portion of the blade 206 can be separated from the side wall of the developing tank 118.

Also, a plate detecting sensor 208 capable of detecting the presence or absence of the PS plate 112 and measuring the plate area, etc. of the delivered plate is installed in the vicinity of this insertion port 202.

The developing tank 118 is formed in an approximately reverse mountain shape in which the upper portion is opened, and the center portion of the bottom is protruded downward. In this developing tank 118, a pump 260 is provided; and the developer in the developing tank 118 is sucked out by this pump 260 and sprayed from spray pipes 144, 272 as described later. In this way, the developer stored in the developing tank 118 is circulated. The developer passes through an electric conductivity sensor 262 which measures the electric conductivity of the developer during this circulation. Also, a replenishing stock liquid is fed into the developing tank 118 from a development replenisher stock liquid tank 266 via a replenishing stock liquid feed pump 264. Further, as described later, dilute water is fed into the developing tank 118 from the water washing tank 128 via a pump 286.

The foregoing 264 and pump 286 are controlled by a control device 50 provided with a control ROM 51a or a control RAM 51b as condition storing means based on signals from the electric conductivity sensor 262 and a time measuring section 52. Incidentally, besides, the action and effect of the control device 50 are the same as in the first embodiment, and therefore, the explanation therefor is omitted.

The developing tank 118 is provided with a guide plate 268 in the upstream side and a number of guide rolls 134 and a rotatory brush roll 270 in the downstream side. These guide rolls 134 and rotatory brush roll 270 are hung in a rotatable manner between a pair of side plates of the developing tank 118.

A guide roll 136 having a comparatively large diameter is provided above the foregoing guide plate 268; a rotatory brush roll 138 and a guide roll 140 are provided above the guide roll 134; and the rotatory brush roll 270 is provided under the guide roll 140. Also, a pair of squeeze rolls 142 provided with a function to squeeze the surface of the PS plate 112 are provided in the center portion in the developing tank 118.

The foregoing overflow pipe 120 is provided in the most downstream side of the developing tank 118, and when the liquid level of the developer exceeds a prescribed level, the developer is guided into a waste liquid tank 284 and disposed.

A liquid level lid 150 is aligned on the surface of the developer in the developing tank 118. In this liquid level lid 150, a portion corresponding to the rotatory brush roll 138 and the guide roll 140 adjacent thereto is protruded in an approximately arc shape. For the purpose of making the contact between the developer surface and air small as far as possible, the liquid level lid 150 is brought into intimate contact with the developer level, and the both ends of the liquid level lid 150 in the delivery direction of the PS plate 112 are installed by a slidable structure against a non-illustrated side plate such that it can go up and down corresponding to the increase or decrease of the developer.

The tip of a blade 274 is brought into contact with the end of the downstream side in the delivery direction of this liquid level lid 150. This blade 274 is fixed to the outside panel 114 via a bracket 276. By this blade 274, the liquid level of the developer exposing from the end of the downstream side in the delivery direction of the liquid level lid 150 is partitioned from the upper portion of the liquid level lid 150; and by the blade 206 in the vicinity of the foregoing insertion port 202 (in the state of contacting with the side wall of the developing tank 118), the upper portion of the liquid level lid 150 is completely isolated from the outside air, whereby evaporation of the developer can be suppressed.

In the most downstream side in the delivery direction of the developing tank 118, a pair of rolls 154 which sandwich and deliver the PS plate 112 and squeeze the developer from the surface of the PS plate 112 are aligned.

On the other hand, the automatic developing equipment 100 is provided with the water washing tank 128 of the water washing section 124 in the downstream side of the developing section 122. Two pairs of delivery rolls 152, 153 are provided in the upper portion of the water washing tank 128.

The washing water after washing out the developer from the PS plate 112 sent out from the developing tank 118 is stored in the water washing tank 128. A spray pipe 156 is provided in the upstream side of the delivery rolls 153 and in the upper side than the delivery passage, and the outer periphery of this spray pipe 156 is provided with plural discharge holes connecting to the inside. Washing water sucked up from a water washing tank 278 by a pump 280 is dropped onto the upper-side roll of the delivery rolls 153 from the spray pipe 156. By rotation of the delivery rolls 153, the washing water is rapidly spread on the surface of the PS plate 112, whereby the surface of the PS plate 112 is washed with the washing water.

Also, the lower portions of the lower-side rolls of the delivery rolls 152, 153 are accommodated in a pan 162. The washing water is stored in the pan 162 and sucked up by the lower-side rolls, thereby washing the rear surface of the PS plate 112 and preventing the upper-side delivery rolls 152, 153 from drying.

Also, the washing water diffused in the widthwise direction on the surface of the PS plate 112 drops in the lower pan 162 from the both ends in the widthwise direction of the PS plate 112, and the rear surface of the PS plate 112 is treated by the washing water sucked up from this pan 162. The washing water overflowed from the pan 162 is guided into the water washing tank 128. The water washing tank 128 is provided with an overflow pipe 282, and when the liquid level exceeds a prescribed liquid level, the washing water is disposed into the waste liquid tank 284.

Also, this water washing tank 128 is connected to the developing tank 118 via the pump 286. By driving the pump 286, the washing water in the water washing tank 128 is guided into the developing tank 118 and can be utilized as a dilute liquid in feeding a replenishing stock liquid into the developing tank 118.

A pair of delivery rolls 178 are provided in the upper portion of the gum liquid tank 130 of the finisher section 126. The PS plate 112 sent out by the delivery rolls 153 is guided into the delivery rolls 178.

Also, in the upstream side of the delivery rolls 178, spray pipes 182, 288 are provided in the upper and lower directions of the delivery passage. A gum liquid sucked up from a gum liquid tank 290 by a pump 292 is discharged from the spray pipes 182, 183 and fed onto the front surface and rear surface of the PS plate 112.

The delivery rolls 178 sandwich and deliver the PS plate 112 and squeeze the gum liquid fed by the spray pipe 182 for the purpose of desensitizing the surface of the PS plate 112. The gum liquid squeezed from the surface of the PS plate 112 is recovered in the gum liquid tank 130. Also, the gum liquid tank 130 is provided with an overflow pipe 296, and when the gum liquid exceeds a prescribed liquid level, the gum liquid is guided into the waste liquid tank 284 and disposed.

Also, the lower portion of the lower-side delivery roll 178 is immersed in the gum liquid stored in the gum liquid tank 130, and the lower-side delivery roll 178 sucks up the gum liquid from the gum liquid tank 130, whereby the rear surface side of the PS plate 112 is subjected to coating processing. In this way, the delivery roll 178 carries the gum liquid to desensitize the rear surface of the PS plate 112 and prevent the upper-side delivery roll 178 from dying, whereby the components of the processing liquid do not deposit on the surfaces of the delivery rolls 178.

The PS plate 112 after completion of the processing in the finisher section 126 passes through the discharge port 204 of a casing 200 and is sent out into a drying section (not illustrated).

Here, the discharge port 204 is provided with a lid 210 as a partition. This lid 210 is fixed to an axis 212. The axis 212 is made rotatable by non-illustrated drive means (for example, solenoid). The rotation of this axis 212 is achieved based on the detection of the PS plate 112 by the foregoing plate detection sensor 208 provided in the vicinity of the insertion port 202. That is, the lid 210 is kept approximately horizontal (in the opened state of the discharge port 204) during a time of detecting the PS plate 112 by the plate detection sensor 208 and a period after the PS plate 112 has not been detected (the rear end has been detected) till elapsing a prescribed time, and besides, it is kept vertical (in the closed state of the discharge port 204).

The action of this embodiment will be described below. First of all, the processing tanks such as the developing tank 118, the water washing tank 128, and the gum liquid tank 130 are covered by the casing 200 such as the outside panel 114 as an upper lid and the body 108. Also, in the state that the development processing of the PS plate 112 is not carried out by the automatic developing equipment 100, the insertion port 202 is closed because the blade 206 comes into contact with the side wall of the developing tank 118. On the other hand, in the discharge port 204, since the PS plate 112 is not detected by the plate detection sensor 208, the lid 210 is laid in the vertical state, and the discharge port 204 is closed. Further, the sub-insertion port 250 is also closed by the blade 252, and the upper portion of the liquid level lid 150 of the developing section 122 is closed by the blades 206, 122. For this reason, the developer in the developing tank 118, the washing water in the water washing section 124, and the gum liquid in the finisher section 126 are not exposed to the outside air and are substantially free from fatigue by carbon dioxide gas. For this reason, since a lowering of the development performance caused due to degradation due to aging can be suppressed, for example, it is possible to markedly drop the replenishing amount of the replenishing stock liquid in the developing section 122. In particular, since the surface of the developer of the developing tank 118 is covered by the liquid level lid 150, an effect for preventing the contact between the developer and the outside air is large.

Incidentally, for the sake of making the contact between the developer and the outside air small as far as possible, it is preferable that the time when the lid 210 is open is short. Accordingly, a structure in which the lid 210 is open only at a time when the PS plate 112 passes and it is closed in other time is preferable.

The control by the control device 50 is identical with the contents of the flow charts of the replenishing method of the development replenisher in FIGS. 2, 3, 4 and 5, and therefore, the explanation therefor is omitted herein.

### EXAMPLES

The invention will be described below with reference to the following Examples, but it should not be construed that the scope of the invention is limited to these Examples. Incidentally, all percentages as used in the Examples are % by weight.

[Preparation of SiO₂-containing Alkaline Developer and Development Replenisher]

To one liter of a 4.0% potassium silicate aqueous solution containing silicon oxide SiO₂ and potassium oxide K₂O having an SiO₂/K₂O mixing ratio of 1.1, a varied development inhibitor was added in an amount as shown in the following Table 1 to prepare alkaline developers (1) to (5) of the invention and a comparative developer (1) having no development inhibitor added thereto.

Also, to one liter of a 6.0% potassium silicate aqueous solution containing silicon oxide SiO₂ and potassium oxide K₂O having an SiO₂/K₂O mixing ratio of 1.1, a varied development inhibitor was added in an amount as shown in the following Table 1 to prepare alkaline development replenishers (1) to (5) of the invention and a comparative development replenisher (1) having no development inhibitor added thereto.

[Preparation of Non-reducing Sugar-containing Alkaline Developer and Development Replenisher]

To one liter of a 5.0% D-sorbitol potassium salt aqueous solution comprising D-sorbitol and potassium oxide K₂O as a combination of a non-reducing sugar and a base, a varied development inhibitor was added in an amount as shown in the following Table 1 to prepare alkaline developers (6) to (10) of the invention and a comparative developer (2) having no development inhibitor added thereto.

Also, to one liter of a 6.5% D-sorbitol potassium salt aqueous solution comprising D-sorbitol and potassium oxide K₂O as a combination of a non-reducing sugar and a base, a varied development inhibitor was added in an amount as shown in the following Table 1 to prepare alkaline development replenishers (6) to (10) of the invention and a comparative development replenisher (2) having no development inhibitor added thereto.

TABLE 1

| Developer | | | Development replenisher | | |
|---|---|---|---|---|---|
| No. | Development inhibitor | Concentration | No. | Development inhibitor | Concentration |
| (1) (6) | POE(3) sorbitol | 0.8 g/L | (1) (6) | POE(3) sorbitol | 1.0 g/L |
| (2) (7) | Ethylenediamine (PO)(EO) | 0.8 g/L | (2) (7) | Ethylenediamine (PO)(EO) | 1.5 g/L |
| | Molecular weight: 1,200 | | | Molecular weight: 1,200 | |
| | EO addition molar ratio: 55% | | | EO addition molar ratio: 55% | |
| (3) (8) | POE(5) cresol ether | 0.6 g/L | (3) (8) | POE(5) cresol ether | 1.2 g/L |
| (4) (9) | POE(10) lauryl ether | 0.6 g/L | (4) (9) | POE(10) lauryl ether | 2.6 g/L |
| (5) (10) | Polyethylene glycol | 0.6 g/L | (5) (10) | Polyethylene glycol | 2.6 g/L |
| | Molecular weight: 1,000 | | | Molecular weight: 1,000 | |
| Comparison | — | — | Comparison | — | — |
| (1) (2) | | | (1) (2) | | |

A heat-sensitive positive lithographic printing plate was subjected to development processing with the foregoing various alkaline development processing liquids.

[Production of Heat-sensitive Positive Lithographic Printing Plate]

An aluminum plate (material quality: 1050) having a thickness of 0.3 mm was washed with trichloroethylene and degreased. Thereafter, the surface of the aluminum plate was sand blasted using a nylon brush and a 400-mesh pumice aqueous suspension and then well washed with water. After washing, this aluminum plate was immersed for etching in a 25% sodium hydroxide aqueous solution at 45° C. for 9 seconds, washed with water, immersed in a 20% nitric acid aqueous solution for 20 seconds, and then again washed with water. At this time, the etching amount of the sand blasted surface was about 3 g/m².

Next, the resulting aluminum plate was provided with an anodically oxidized film of 3 g/m² using 7% sulfuric acid as an electrolytic liquid and a direct current having a current density of 15 A/dm², washed with water, and then dried. The resulting aluminum plate was treated with a 2.5% sodium silicate aqueous solution at 30° C. for 10 seconds and coated with a coating liquid for undercoat layer at 80° C. for 15 seconds to obtain a support. The coating amount after drying of the undercoat layer was 15 mg/m².

<Coating liquid for undercoat layer>

| | |
|---|---|
| Copolymer P described below (molecular weight: 28,000): | 0.3 g |
| Methanol: | 100 g |
| Water: | 1 g |

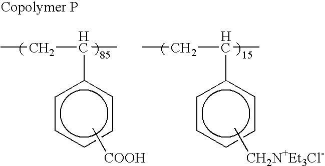

### Synthesis Example 1

### Synthesis of Carboxyl Group-containing Alkali-soluble High Molecular Compound (Copolymer)

A 20-mL three-necked flask equipped with a stirrer, a condenser tube and a dropping funnel was charged with 6.39 g (0.045 moles) of n-propyl methacrylate, 1.29 g (0.015 moles) of methacrylic acid, and 20 g of 1-methoxy-2-propanol, and the mixture was stirred while heating on a warm water bath at 65° C. 0.15 g of “V-601” (manufactured by Wako Pure Chemical Industries, Ltd.) was added to this mixture, and the mixture was stirred under a nitrogen gas stream for 2 hours while keeping at 70° C. To the reaction mixture, a mixture of 6.39 g (0.045 moles) of n-propyl methacrylate, 1.29 g (0.015 moles) of methacrylic acid, 20 g of 1-methoxy-2-propanol, and 0.15 g of “V-601” was further dropped over 2 hours from the dropping funnel. After completion of dropping, the resulting mixture was further stirred at 90° C. for 2 hours. After completion of the reaction, 40 g of methanol was added to the mixture and cooled. The resulting mixture was thrown into two liters of water while stirring this water, and the mixture was stirred for 30 minutes. A deposit was taken out by filtration and dried to obtain 15 g of a white solid. The weight average molecular weight (as reduced into polystyrene) of this copolymer was measured by gel permeation chromatography and found to be 53,000.

### Synthesis Example 2

### Synthesis of Carboxyl Group-containing Alkali-soluble High Molecular Compound (Copolymer)

A copolymer was synthesized using a mixture of ethyl methacrylate, isobutyl methacrylate and methacrylic acid (molar ratio: 35/35/30) in the same procedures as in the foregoing Synthesis Example 1. The weight average molecular weight (as reduced into polystyrene) of this copolymer was measured and found to be 50,000.

### Synthesis Example 3

### Synthesis of Carboxyl Group-containing Polyurethane Resin

A 500-mL three-necked round bottom flask equipped with a condenser tube and a stirrer was charged with 14.6 g (0.109 moles) of 2,2-bis(hydroxymethyl)propionic acid, 13.3 g (0.0686 moles) of tetraethylene glycol, and 2.05 g (0.0228 moles) of 1,4-butanediol, and the mixture was dissolved in 118 g of N,N-dimethylacetamide. To this mixture, 30.8 g (0.123 moles) of 4,4′-diphenylmethane diisocyanate, 13.8 g (0.0819 moles) of hexamethylene diisocyanate, and 0.1 g of di-n-butyltin dilaurate as a catalyst were added and heated at 90° C. for 7 hours under stirring. To the reaction mixture, 100 mL of N,N-dimethylacetamide, 50 mL of methanol, and 50 mL of acetic acid. After stirring, the mixture was thrown into 4 liters of water while stirring to deposit a white polymer. This polymer was filtered out, washed with water, and then dried in vacuo to obtain 60 g of a polymer.

The molecular weight of the polymer was measured by gel permeation chromatography (GPC). As a result, the weight average molecular weight (as reduced into polystyrene) was found to be 70,000. Also, the carboxyl group content was measured by titration and found to be 1.43 meq/g.

### Synthesis Example 4

### Synthesis of Carboxyl Group-containing Polyurethane Resin

A copolymer was synthesized using the following diisocyanate compounds (% by mole): 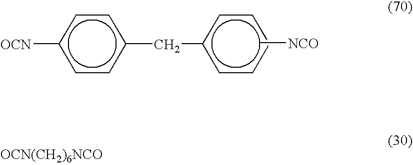
and the following diol compounds (% by mole): 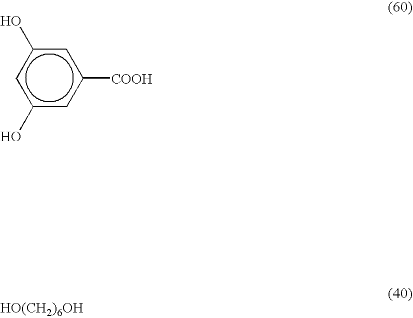
in the same manner as in Synthesis Example 3. The acid content of the resulting copolymer was measured by titration and found to be 1.72 meq/g. Also, its weight average molecular weight (as reduced into polystyrene) was found to be 80,000.

### Synthesis Example 5

A 500-mL three-necked flask equipped with a stirrer, a condenser tube and a dropping funnel was charged with 31.0 g (0.36 moles) of methacrylic acid, 39.1 g (0.36 moles) of ethyl chloroformate and 200 mL of acetonitrile, and the mixture was stirred under cooling on an ice water bath. To this mixture, 36.4 g (0.36 moles) of triethylamine was dropped over about one hour from the dropping funnel. After completion of dropping, the ice water bath was removed, and the mixture was stirred at room temperature for 30 minutes. To the reaction mixture, 51.7 g (0.30 moles) of p-aminobenzenesulfonamide was added, and the mixture was stirred for one hour while warming on an oil bath at 70° C. After completion of the reaction, the reaction mixture was thrown into one liter of water while stirring this water, and the resulting mixture was stirred for 30 minutes. This mixture was filtered to take out a deposit, which was then formed into a slurry upon addition of 500 mL of water. This slurry was filtered, and the thus obtained solid was dried to obtain a white solid of N-(p-aminosulfonylphenyl)methacrylamide (yield: 46.9 g). Next, a 20-mL three-necked flask equipped with a stirrer, a condenser tube and a dropping funnel was charged with 4.61 g (0.0192 moles) of N-(p-aminosulfonylphenyl)-methacrylamide, 2.94 g (0.0258 moles) of ethyl methacrylate, 0.80 g (0.015 moles) of acrylonitrile, and 20 g of N,N-dimethylacetamide, and the mixture was stirred while heating on a warm water bath at 65° C. To this mixture, 0.15 g of “V-65” (manufactured by Wako Pure Chemical Industries, Ltd.) was added, and the mixture was stirred under a nitrogen gas stream for 2 hours while keeping at 65° C. To the reaction mixture, a mixture of 4.61 g of N-(p-amino-sulfonylphenyl)methacrylamide, 2.94 g of ethyl methacrylate, 0.80 g of acrylonitrile, N,N-dimethylacetamide, and 0.15 g of “V-65” was further dropped over 2 hours from the dropping funnel. After completion of dropping, the resulting mixture was further stirred at 65° C. for 2 hours. After completion of the reaction, 40 g of methanol was added to the mixture and cooled. The resulting mixture was thrown into two liters of water while stirring this water, and the mixture was stirred for 30 minutes. A deposit was taken out and dried to obtain 15 g of a white solid. The weight average molecular weight (as reduced into polystyrene) of this specified copolymer was measured by gel permeation chromatography and found to be 53,000.

A coating liquid for image recording layer described below was coated on the resulting support and dried at 150° C. for 30 seconds such that the coating amount after drying was 1.8 g/m², to obtain a positive lithographic printing plate precursor A.

<Coating liquid for image recording layer>

| | | |
|---|---|---|
| Copolymer of the foregoing Synthetic Example 2: | 0.050 | g |
| Copolymer of the foregoing Synthetic Example 4: | 0.050 | g |
| Copolymer of the foregoing Synthetic Example 5: | 0.4 | g |
| m,p-Cresol novolak (m/p ratio = 6/4, weight | 0.6 | g |
| average molecular weight: 8,000, containing | | |
| 0.5% of unreacted cresol): | | |
| Cyanine dye A: | 0.1 | g |
| Phthalic anhydride: | 0.05 | g |
| p-Toluenesulfonic acid: | 0.002 | g |
| Ethyl Violet (counter ion: 6-hydroxy-β-naphthalenesulfonic | 0.02 | g |
| acid): | | |
| Esterified product of naphthoquinone | 0.01 | g |
| 1,2-diazido-5-sulfonyl chloride and pyrogallol/acetone resin: | | |
| Fluorine based surfactant (trade name: Megafac F-177, | 0.05 | g |
| manufactured by Dainippon Ink and | | |
| Chemicals, Incorporated): | | |
| Methyl ethyl ketone: | 8 | g |
| 1-Methoxy-2-propanol: | 4 | g |

On an aluminum support provided with an undercoat layer processed in the same manner as describe previously, the following coating liquid I for image recording layer was coated using a wire bar such that the coating amount after drying was 0.85 g/m² and then dried at 140° C. for 50 seconds while setting up the WindControl at 7 by TABAI's PERFECT OVER PH200. Further, the following coating liquid 2 for image recording layer was coated thereon using a wire bar such that the coating amount after drying was 0.22 g/m² and then dried at 120° C. for 60 seconds while setting up the WindControl at 7 by TABAI's PERFECT OVER PH200. There was thus obtained a lithographic printing plate precursor B having an image forming layer having a two-layer construction.

<Coating liquid 1 for image recording layer>

| | |
|---|---|
| Copolymer of the foregoing Synthetic Example 2: | 0.050 g |
| Copolymer of the foregoing Synthetic Example 4: | 0.050 g |
| N-(4-Aminosulfonylphenyl)methacrylamide/acrylonitrile/methyl | 1.896 g |
| methacrylate (36/34/30) (weight average molecular | |
| weight: 50,000): | |
| Cresol novolak (m/p ratio = 6/4, weight average molecular | 0.237 g |
| weight: 4,500, content of residual monomer: 0.8% by weight): | |
| Cyanine dye A: | 0.109 g |
| 4,4'-Bishydroxyphenylsulfone: | 0.063 g |
| Tetrahydrophthalic anhydride: | 0.190 g |
| p-Toluenesulfonic acid: | 0.008 g |
| Ethyl Violet in which the counter ion thereof is changed to | 0.05 g |
| 6-hydroxynaphthalenesulfone: | |
| Fluorine based surfactant (F176, manufactured by Dainippon | 0.035 g |
| Ink and Chemicals, Incorporated): | |
| Methyl ethyl ketone: | 26.6 g |
| 1-Methoxy-2-propanol: | 13.6 g |
| γ-Butyrolactone: | 13.8 g |

<Coating liquid 2 for image recording layer>

| | |
|---|---|
| Copolymer of the foregoing Synthetic Example 2: | 0.050 g |
| Copolymer of the foregoing Synthetic Example 4: | 0.050 g |
| Cresol novolak (m/p ratio = 6/4, weight average molecular | 0.237 g |
| weight: 4,500, content of residual monomer: 0.8% by weight): | |
| Cyanine dye A: | 0.047 g |
| Dodecyl stearate: | 0.060 g |
| 3-Methoxy-4-diazodiphenylamine hexafluorophosphate: | 0.030 g |
| Fluorine based surfactant (F176 (20% solution), manufactured | 0.110 g |
| by Dainippon Ink and Chemicals, Incorporated): | |
| Fluorine based surfactant (MCF312F (30% solution), | 0.12 g |
| manufactured by Dainippon Ink and Chemicals, Incorporated): | |
| Methyl ethyl ketone: | 15.1 g |
| 1-Methoxy-2-propanol: | 7.7 g |

Each of the resulting lithographic printing plate precursors A and B was exposed using semi-conductor laser having an output of 500 mW, a wavelength of 830 nm, and a beam diameter of 17 μm (1/e²) at a main scanning rate of 5 n/sec and kept at 25° C. With respect to the case where the resulting lithographic printing plates were subjected to the replenishing method of a development replenisher in each of the foregoing embodiments and the conventional replenishing method of a development replenisher, respectively, a fluctuation width in sensitivity of the developer was experimentally determined.

### Processing of Examples 1 to 12

As shown in Tables 2 and 3, the continuous processing was carried out by utilizing the replenishing method of the invention, thereby evaluating the stability of sensitivity of the developer. With respect to the evaluation of the stability of development sensitivity, how the image density of an image having a gradation density of 50% obtained by exposure by halftoning the photosensitive material (AM screening, screen line number: 175 lpi) was changed by the development processing. The results obtained are shown in Table 4.

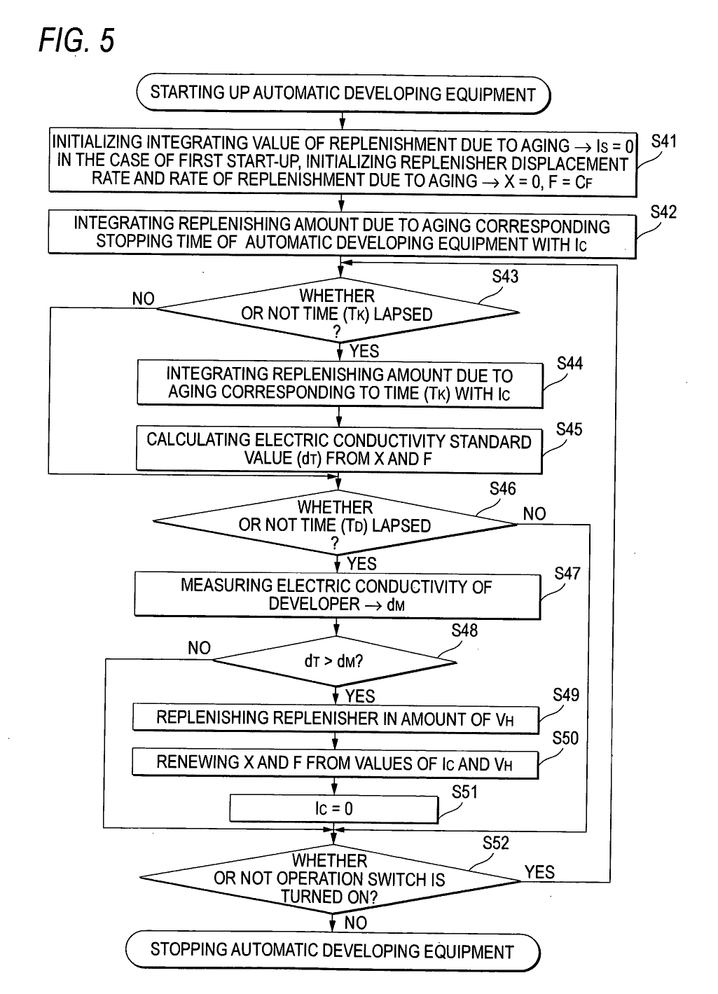

TABLE 2

| | | Lithographic | | | |
|---|---|---|---|---|---|
| | | printing plate | | | Processing |
| | Replenishment mode | precursor | Developer | Replenisher | condition |
| Example 1 | System of the invention | A, B | (1) | (1) | Processing |
| | (Control system of FIG. 5) | | | | condition 1 |
| Example 2 | System of the invention | A, B | (1) | (1) | Processing |
| | (Control system of FIG. 5) | | | | condition 2 |
| Example 3 | System of the invention | A, B | (2) | (2) | Processing |
| | (Control system of FIG. 5) | | | | condition 1 |
| Example 4 | System of the invention | A, B | (3) | (3) | Processing |
| | (Control system of FIG. 5) | | | | condition 1 |
| Example 5 | System of the invention | A, B | (4) | (4) | Processing |
| | (Control system of FIG. 5) | | | | condition 1 |
| Example 6 | System of the invention | A, B | (5) | (5) | Processing |
| | (Control system of FIG. 5) | | | | condition 1 |
| Example 7 | System of the invention | A, B | (6) | (6) | Processing |
| | (Control system of FIG. 5) | | | | condition 1 |
| Example 8 | System of the invention | A, B | (6) | (6) | Processing |
| | (Control system of FIG. 5) | | | | condition 2 |
| Example 9 | System of the invention | A, B | (7) | (7) | Processing |
| | (Control system of FIG. 5) | | | | condition 1 |
| Example 10 | System of the invention | A, B | (8) | (8) | Processing |
| | (Control system of FIG. 5) | | | | condition 1 |
| Example 11 | System of the invention | A, B | (9) | (9) | Processing |
| | (Control system of FIG. 5) | | | | condition 1 |
| Example 12 | System of the invention | A, B | (10) | (10) | Processing |
| | (Control system of FIG. 5) | | | | condition 1 |
| Comparative | System of the invention | A, B | Comparison (1) | Comparison (1) | Processing |
| Example 1 | (Control system of FIG. 5) | | | | condition 1 |
| Comparative | System of the invention | A, B | Comparison (2) | Comparison (2) | Processing |
| Example 2 | (Control system of FIG. 5) | | | | condition 1 |
| Comparative | Area-based replenishing system | A, B | (1) | (1) | Processing |
| Example 3 | due to aging (not including | | | | condition 3 |
| | detection of electric | | | | |
| | conductivity) | | | | |
| Comparative | Area-based replenishing system | A, B | (2) | (2) | Processing |
| Example 4 | due to aging (not including | | | | condition 3 |
| | detection of electric | | | | |
| | conductivity) | | | | |
| Comparative | Area-based replenishing system | A, B | (1) | (1) | Processing |
| Example 5 | due to aging (not including | | | | condition 4 |
| | detection of electric | | | | |
| | conductivity) | | | | |
| Comparative | Area-based replenishing system | A, B | (2) | (2) | Processing |
| Example 6 | due to aging (not including | | | | condition 4 |
| | detection of electric | | | | |
| | conductivity) | | | | |

TABLE 3

| | | | | | Replenishing | Replenishing | | |
|---|---|---|---|---|---|---|---|---|
| | | | | | amount due to | amount due to | | |
| | Automatic | Volume of | | | aging at the | aging at the | Replenishing | |
| | developing | developing | Development | Development | time of | time of | amount for | |
| | equipment | tank | temperature | time | operation | stopping | processing | |
| Processing | | 20,000 cc | 30° C. | 12 seconds | — | — | — | |
| condition 1 | | | | | | | | |
| Processing | | 20,000 cc | 30° C. | 12 seconds | — | — | — | |
| condition 2 | | | | | | | | |
| Processing | | 20,000 cc | 30° C. | 12 seconds | 220 cc/h | 100 cc/h | 40 | cc/m² |
| condition 3 | | | | | | | | |
| Processing | | 20,000 cc | 30° C. | 12 seconds | 50 cc/h | 15 cc/h | 20 | cc/h |
| condition 4 | | | | | | | | |

Processing amount: common in lithographic printing plate precursors A and B
Processing amount per day: area per plate: 0.8 m², 13 plates

TABLE 4

| | Change of 50% gradation density (the density at the | | | | | | | | | |
|---|---|---|---|---|---|---|---|---|---|---|
| | time of start on the first day being defined as ±0.0%) | | | | | | | | | |
| | Date | | | | | | | | | |
| | 1 | 2 | 3 | 4 | 5 | 8 | 9 | 10 | 11 | 12 |
| Example 1 | ±0.0% | +0.25% | +0.25% | −1.25% | −1.25% | −1.25% | −1.25% | −0.15% | +1.0% | +1.5% |
| Example 2 | ±0.0% | −0.25% | ±0.0% | −1.25% | −1.5% | −1.5% | −1.25% | +0.25% | +1.25% | +1.75% |
| Example 3 | ±0.0% | +0.25% | +0.25% | −1.25% | −1.25% | −1.25% | −1.25% | −0.15% | +1.0% | +1.5% |
| Example 4 | ±0.0% | +0.25% | +0.25% | −1.25% | −1.25% | −1.25% | −1.25% | −0.15% | +1.0% | +1.5% |
| Example 5 | ±0.0% | +0.25% | +0.25% | −1.25% | −1.25% | −1.25% | −1.25% | −0.15% | +1.0% | +1.5% |
| Example 6 | ±0.0% | +0.25% | +0.25% | −1.25% | −1.25% | −1.25% | −1.25% | −0.15% | +1.0% | +1.5% |
| Example 7 | ±0.0% | +0.25% | +0.25% | −1.25% | −1.25% | −1.25% | −1.25% | −0.15% | +1.0% | +1.5% |
| Example 8 | ±0.0% | −0.25% | ±0.0% | −1.25% | −1.5% | −1.5% | −1.25% | +0.25% | +1.25% | +1.75% |
| Example 9 | ±0.0% | +0.25% | +0.25% | −1.25% | −1.25% | −1.25% | −1.25% | −0.15% | +1.0% | +1.5% |
| Example 10 | ±0.0% | +0.25% | +0.25% | −1.25% | −1.25% | −1.25% | −1.25% | −0.15% | +1.0% | +1.5% |
| Example 11 | ±0.0% | +0.25% | +0.25% | −1.25% | −1.25% | −1.25% | −1.25% | −0.15% | +1.0% | +1.5% |
| Example 12 | ±0.0% | +0.25% | +0.25% | −1.25% | −1.25% | −1.25% | −1.25% | −0.15% | +1.0% | +1.5% |
| Comparative Example 1 | ±0.0% | ±0.0% | +0.25% | +0.25% | +0.25% | −0.5% | −1.25% | −0.5% | +1.0% | +2.5% |
| Comparative Example 2 | ±0.0% | ±0.0% | +0.25% | +0.25% | +0.25% | −0.5% | −1.25% | −0.5% | +1.0% | +2.5% |
| Comparative Example 3 | ±0.0% | ±0.0% | ±0.0% | +0.25% | +0.25% | +0.75% | +1.5% | +2.75% | +3.75% | +4.25% |
| Comparative Example 4 | ±0.0% | −0.25% | +0.25% | +0.25% | ±0.0% | +1.25% | +1.5% | +2.5% | +3.5% | +4.0% |
| Comparative Example 5 | ±0.0% | ±0.0% | ±0.0% | +0.25% | +0.25% | +0.75% | +1.5% | +2.75% | +3.75% | +4.25% |
| Comparative Example 6 | ±0.0% | −0.25% | +0.25% | +0.25% | ±0.0% | +1.25% | +1.5% | +2.5% | +3.5% | +4.0% |

### Processing of Comparative Examples 1 to 6

As shown in Tables 2 to 3, the continuous processing was carried out with the developer not containing development inhibitor concerning Comparative Examples 1 and 2, and the continuous processing was carried out by utilizing the area-based replenishing system due to aging concerning Comparative Examples 3 to 6, thereby evaluating the stability of sensitivity of the developer. With respect to the evaluation of the stability of development sensitivity, how the image density of an image having a gradation density of 50% obtained by exposure by halftoning the photosensitive material (AM screening, screen line number: 175 lpi) was changed by the development processing. The results obtained are shown in Table 4.

It could be confirmed from the foregoing evaluation that Examples 1 to 12 fall within a tolerable range in the change of the 50% gradation density of from −2.0% to +2.0%, whereas Comparative Examples 1 to 6 exceed the foregoing tolerable range of the 50% gradation density.

1. A replenishing method of a development replenisher in an automatic developing equipment of photosensitive lithographic printing plate including:
developing plural photosensitive lithographic printing plates having been subjected to exposure processing with a developer containing an electrolyte and a development inhibitor; and
keeping a developer activity of the developer constant, the method comprises:
measuring an electric conductivity of the developer to obtain an electric conductivity value;
comparing the electric conductivity value with an electric conductivity standard value; and
replenishing the development replenisher having a concentration of the development inhibitor higher than that of the developer, when the electric conductivity value of the developer is lower than the electric conductivity standard value.

2. The replenishing method according to claim 1, wherein the electric conductivity standard value is an electric conductivity value operated from a total processing amount of the photosensitive lithographic printing plate having been processed with the developer.

3. The replenishing method according to claim 2, wherein the method further comprises renewing the processing area when a processing has been performed.

4. The replenishing method according to claim 1, wherein the electric conductivity standard value is an electric conductivity value operated from a replenisher displacement rate which is a rate of the development replenisher replenished in the developer to the developer.

5. The replenishing method according to claim 4, wherein the method further comprises renewing the replenisher displacement rate after replenishing.

6. The replenishing method according to claim 1, wherein the electric conductivity standard value is an electric conductivity value operated from
a replenishing rate due to aging which is a rate of an amount of replenisher due to aging operated from an operation time and a stopping time of the automatic developing equipment to a total replenishing amount and
a replenisher displacement rate which is a rate of the development replenisher replenished in the developer to the developer.

7. The replenishing method according to claim 6, wherein the method further comprises renewing the replenishing rate due to aging and the replenisher displacement rate after replenishing.

8. The replenishing method according to claim 1, wherein the development inhibitor in the development replenisher has a concentration of from 1.1 to 50 times that in the develper.
